(19) United States
(12) Patent Application Publication
(10) Pub. No.: US 2023/0352606 A1
(43) Pub. Date: Nov. 2, 2023

(54) SHORT-WAVE INFRARED AND MID-WAVE INFRARED OPTOELECTRONIC DEVICE AND METHODS FOR MANUFACTURING THE SAME

(71) Applicants: OUSSAMA MOUTANABBIR, Montréal, Quebec (CA); MAHMOUD ATALLA, Montréal, Quebec (CA); SIMONE ASSALI, Montréal, Quebec (CA); ANIS ATTIAOUI, Montréal, Quebec (CA)

(72) Inventors: OUSSAMA MOUTANABBIR, Montréal, Quebec (CA); MAHMOUD ATALLA, Montréal, Quebec (CA); SIMONE ASSALI, Montréal, Quebec (CA); ANIS ATTIAOUI, Montréal, Quebec (CA)

(21) Appl. No.: 17/921,724

(22) PCT Filed: Apr. 27, 2021
(86) PCT No.: PCT/CA2021/050579

§ 371 Date: Oct. 27, 2022

Related U.S. Application Data
(60) Provisional application No. 63/015,766, filed on Apr. 27, 2020.

(51) Int. Cl. H01L 31/028; H01L 33/34; H01L 33/00; H01L 31/18

(52) U.S. Cl. CPC H01L 31/028; H01L 33/34; H01L 33/002; H01L 33/0054; H01L 31/1812; H01L 31/1892; H01L 33/0093

(57) ABSTRACT

There is provided an optoelectronic device having an operation range reaching and exceeding 4 μm. The optoelectronic device includes a silicon or a silicon-based substrate and a heterostructure at least partially extending over the substrate. The heterostructure includes a stack of coextending photoactive layers and each photoactive layer includes one or two group IV elements. The photoactive layers are configured for absorbing and/or emitting short-wave infrared and mid-wave infrared radiation. In some embodiments, the short-wave infrared and mid-wave infrared radiation is in a wavelength range extending from about 1 μm to about 8 μm. Methods for manufacturing such an optoelectronic device and device processing are also provided. The methods include forming a heterostructure on a substrate, releasing the heterostructure from the substrate to form a relaxed membrane and transferring the relaxed membrane on a host substrate.

### TECHNICAL FIELD

The technical field generally relates to optoelectronic devices and methods for producing the same, and more particularly to short-wave infrared and mid-wave infrared optoelectronic devices, including light-emitting diodes and photodetectors, as well as methods for manufacturing the same.

### BACKGROUND

Existing detectors operating in the short-wave infrared and mid-wave infrared range include III-V and II-VI compounds, such as, for example: InSb (operating from about 2 μm to about 5.5 μm), HgCdTe (operating from about 3 μm to 7 μm), and PbSe (operating from about 1 μm to 5.2 μm). These detectors typically need cooling and vacuum-packaging to reach sufficient signal-to-noise ratio (SNR). In addition, these technologies are difficult or even impossible to integrate with silicon photonics. The existing short-wave infrared and mid-wave infrared detectors are also associated with high costs, which may be attributed primarily to the high cost of materials used. The overall costs of a megapixel mid-wave infrared detector may exceed tens of thousands of dollars. Furthermore, the poor or limited integrability of the existing technologies limits their compactness and thus their deployability. These limitations hinder the broad adoption of short-wave infrared and mid-wave infrared technologies, especially in the civilian markets.

Challenges still exist in the field of short-wave infrared and mid-wave infrared optoelectronic devices, and their implementation in different devices, as well as methods for manufacturing the same.

### SUMMARY

In accordance with one aspect, there is provided an optoelectronic device having an operation range extending above 4 μm and that may be operated at room temperature or at a cryogenic temperature. The optoelectronic device includes a silicon substrate or a silicon-based substrate and a heterostructure at least partially extending over the substrate. The heterostructure includes a stack of coextending photoactive layers and each photoactive layer includes one or two group IV elements. The photoactive layers are configured for absorbing and/or emitting short-wave infrared and mid-wave infrared radiation. In some embodiments, the short-wave infrared and mid-wave infrared radiation is included in a wavelength range extending from about 1 μm to about least 8 μm.

In accordance with another aspect, there is provided an optoelectronic device, including:
a silicon-based substrate;
a heterostructure at least partially extending over the silicon-based substrate, the heterostructure including a stack of coextending photoactive layers, each photoactive layer including at least two group IV elements and being configured for absorbing short-wave infrared and mid-wave infrared radiation, the short-wave infrared and mid-wave infrared radiation being in a wavelength range extending from about 1 μm to about 8 μm; and
electrodes operatively connected to the heterostructure.

In some embodiments, said at least two group IV elements are selected from the group consisting of: Si, Ge and Sn.

In some embodiments, the wavelength range extends from about 2 μm to about 8 μm.

In some embodiments, the wavelength range extends from about 1 μm to about 1.7 μm.

In some embodiments, the wavelength range extends from about 1 μm to about 2.7 μm.

In some embodiments, the wavelength range extends from about 1 μm to about 3.3 μm.

In some embodiments, the wavelength range extends from about 1 μm to about 3.5 μm.

In some embodiments, the stack of coextending photoactive layers includes at least one GeSn-based layer.

In some embodiments, the stack of coextending photoactive layers includes at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, the optoelectronic device, further includes a Ge virtual substrate extending over the silicon-based substrate.

In some embodiments, the optoelectronic device is operable at room temperature.

In some embodiments, the optoelectronic device is operable at a cryogenic temperature.

In some embodiments, the cryogenic temperature is equal or greater than about 77 K.

In some embodiments, each photoactive layer has a strain included in a range extending between about −2% to about +2%.

In accordance with another aspect, there is provided a photodetector, including:
a silicon-based substrate;
a heterostructure at least partially extending over the silicon-based substrate, the heterostructure including a stack of coextending photoactive layers, each photoactive layer including at least two group IV elements and being configured for detecting short-wave infrared and mid-wave infrared radiation, the short-wave infrared and mid-wave infrared radiation being in a wavelength range extending from about 1 μm to about 8 μm; and
electrodes operatively connected to the heterostructure.

In some embodiments, said at least two group IV elements are selected from the group consisting of: Si, Ge and Sn.

In some embodiments, the wavelength range extends from about 2 μm to about 8 μm.

In some embodiments, the wavelength range extends from about 1 μm to about 1.7 μm.

In some embodiments, the wavelength range extends from about 1 μm to about 2.7 μm.

In some embodiments, the wavelength range extends from about 1 μm to about 3.3 μm.

In some embodiments, the wavelength range extends from about 1 μm to about 3.5 μm.

In some embodiments, the stack of coextending photoactive layers includes at least one GeSn-based layer.

In some embodiments, the stack of coextending photoactive layers includes at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, the photodetector, further includes a Ge virtual substrate extending over the silicon-based substrate.

In some embodiments, the photodetector is operable at room temperature.

In some embodiments, the optoelectronic device is operable at a cryogenic temperature.

In some embodiments, the cryogenic temperature is equal or greater than about 77 K.

In some embodiments, each photoactive layer has a strain included in a range extending between about −2% to about +2%.

In accordance with another aspect, there is provided a light-emitting diode, including:
a silicon-based substrate;
a heterostructure at least partially extending over the silicon-based substrate, the heterostructure including a stack of coextending photoactive layers, each photoactive layer including at least two group IV elements and being configured for emitting short-wave infrared and mid-wave infrared radiation, the short-wave infrared and mid-wave infrared radiation being in a wavelength range extending from about 1 μm to about 8 μm; and
electrodes operatively connected to the heterostructure.

In some embodiments, said at least two group IV elements are selected from the group consisting of: Si, Ge and Sn.

In some embodiments, wavelength range extends from about 2 μm to about 8 μm.

In some embodiments, the wavelength range extends from about 1 μm to about 1.7 μm.

In some embodiments, the wavelength range extends from about 1 μm to about 2.7 μm.

In some embodiments, the wavelength range extends from about 1 μm to about 3.3 μm.

In some embodiments, the wavelength range extends from about 1 μm to about 3.5 μm.

In some embodiments, the stack of coextending photoactive layers includes at least one GeSn-based layer.

In some embodiments, the stack of coextending photoactive layers includes at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, the light-emitting diode further includes a Ge virtual substrate extending over the silicon-based substrate.

In some embodiments, the light-emitting diode is operable at room temperature.

In some embodiments, the optoelectronic device is operable at a cryogenic temperature.

In some embodiments, the cryogenic temperature is equal or greater than about 77 K.

In some embodiments, each photoactive layer has a strain included in a range extending between about −2% to about +2%.

In accordance with another aspect, there is provided an optoelectronic platform, including:
a silicon-based substrate;
a heterostructure at least partially extending over the silicon-based substrate, the heterostructure including a stack of coextending photoactive layers, each photoactive layer including at least two group W elements and being configured to perform at least one of:
   emitting short-wave infrared and mid-wave infrared radiation; and
   detecting the short-wave infrared and mid-wave infrared radiation,
   wherein the short-wave infrared and mid-wave infrared radiation is in a wavelength range extending from about 1 μm to about 8 μm; and
electrodes operatively connected to the heterostructure.

In some embodiments, said at least two group IV elements are selected from the group consisting of: Si, Ge and Sn.

In some embodiments, the wavelength range extends from about 2 μm to about 8 μm.

In some embodiments, the wavelength range extends from about 2 μm to about 2.8 μm.

In some embodiments, the wavelength range extends from about 1 μm to about 1.7 μm.

In some embodiments, the wavelength range extends from about 1 μm to about 2.7 μm.

In some embodiments, the wavelength range extends from about 1 μm to about 3.3 μm.

In some embodiments, the wavelength range extends from about 1 μm to about 3.5 μm.

In some embodiments, the stack of coextending photoactive layers includes at least one GeSn-based layer.

In some embodiments, the stack of coextending photoactive layers includes at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, the optoelectronic platform further includes a Ge virtual substrate extending over the silicon-based substrate.

In some embodiments, the optoelectronic platform is operable at room temperature.

In some embodiments, the optoelectronic device is operable at a cryogenic temperature.

In some embodiments, the cryogenic temperature is equal or greater than about 77 K.

In some embodiments, each photoactive layer has a strain included in a range extending between about −2% to about +2%.

In accordance with another aspect, there is provided a method for manufacturing an optoelectronic device, including:
conditioning a reactor chamber to reach initial growth conditions;
forming a heterostructure on a substrate provided inside the reactor chamber, including:
   forming a first group IV alloy layer by exposing the substrate to the initial growth conditions;
   conditioning the reactor chamber to reach subsequent growth conditions; and
   forming at least one subsequent group IV alloy layer on the group IV alloy layer by exposing the first group IV alloy layer to the subsequent growth conditions, each group IV alloy layer in the heterostructure having a different or relatively similar Sn content one from another;
releasing the heterostructure from the substrate to form a relaxed membrane; and
transferring the relaxed membrane on a host substrate.

In some embodiments, the group IV alloy layers includes at least two group IV elements selected from the group consisting of Si, Ge and Sn.

In some embodiments, the method further includes n-doping at least one of the group IV alloy layers.

In some embodiments, the method further includes p-doping at least one of the group IV alloy layers.

In some embodiments, the method further includes forming group IV alloy multi-quantum wells.

In some embodiments, the method further includes patterning the heterostructure to obtain an array of structures.

In some embodiments, the substrate includes a virtual substrate layer extending over an original substrate layer and wherein said releasing the heterostructure from the substrate includes etching portions of the heterostructure and the virtual substrate until the heterostructure collapses on the original substrate.

In some embodiments, said etching the portions of the heterostructure and the virtual substrate includes:
anisotropically etching the portions of the heterostructure and portions of the virtual substrate with Cl₂; and
isotropically etching remaining portions of the virtual substrate with CF₄.

In some embodiments, the method further includes forming a metallic contact operatively connecting the heterostructure with the substrate.

In some embodiments, said forming the heterostructure includes forming at least one GeSn-based layers.

In some embodiments, said forming the heterostructure includes forming at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, there is provided an optoelectronic device manufactured according to the method herein described.

In accordance with another aspect, there is provided a method for manufacturing an optoelectronic device, including:
forming a heterostructure on a substrate provided inside a reactor chamber, including:
   forming a first group IV alloy layer by exposing the substrate to initial growth conditions; and
   forming at least one subsequent group IV alloy layer on the group IV alloy layer; and
varying a precursor concentration inside the reactor chamber while forming the heterostructure to obtain subsequent growth conditions, such that each group IV alloy layer in the heterostructure has a different Sn content one from another upon exposure to the subsequent growth conditions.

In some embodiments, the group IV alloy layers includes at least two group IV elements selected from the group consisting of Si, Ge and Sn.

In some embodiments, the method further includes n-doping at least one of the group IV alloy layers.

In some embodiments, the method further includes p-doping at least one of the group IV alloy layers.

In some embodiments, the method further includes forming group IV alloy multi-quantum wells.

In some embodiments, the method further includes patterning the heterostructure to obtain an array of structures.

In some embodiments, the method further includes forming a metallic contact operatively connecting the heterostructure with the substrate.

In some embodiments, said forming the heterostructure includes forming at least one GeSn-based layers.

In some embodiments, said forming the heterostructure includes forming at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, there is provided an optoelectronic device manufactured according to the method herein described.

In accordance with another aspect, there is provided a light-emitting diode, including:
a silicon-based substrate;
a heterostructure at least partially extending over the silicon-based substrate, the heterostructure including a stack of coextending photoactive layers, each photoactive layer including at least two group IV elements and being configured for emitting short-wave infrared and mid-wave infrared radiation, the short-wave infrared and mid-wave infrared radiation being in a wavelength range extending from about 2 μm to about 2.8 μm; and
electrodes operatively connected to the heterostructure.

In some embodiments, the light-emitting diode has a diameter of about 40 μm.

In some embodiments, the stack of coextending photoactive layers includes at least one GeSn-based layer.

In some embodiments, the stack of coextending photoactive layers includes at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, each of said at least two GeSn-based layers has a different thickness one from another.

In some embodiments, the light-emitting diode further includes a Ge virtual substrate extending over the silicon-based substrate.

In some embodiments, the light-emitting diode is operable at room temperature.

In some embodiments, the optoelectronic device is operable at a cryogenic temperature.

In some embodiments, the cryogenic temperature is equal or greater than about 77 K.

In some embodiments, each photoactive layer has a strain included in a range extending between about −2% to about +2%.

In accordance with another aspect, there is provided a photodetector, including:
a silicon-based substrate;
a heterostructure at least partially extending over the silicon-based substrate, the heterostructure including a stack of coextending photoactive layers, each photoactive layer including at least two group IV elements and being configured for detecting short-wave infrared and mid-wave infrared radiation, the short-wave infrared and mid-wave infrared radiation being in a wavelength range extending from about 1 μm to about 2.6 μm; and
electrodes operatively connected to the heterostructure.

In some embodiments, the photodetector has a diameter included in a range extending from about 20 μm to about 160 μm.

In some embodiments, the stack of coextending photoactive layers includes at least one GeSn-based layer.

In some embodiments, the stack of coextending photoactive layers includes at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, the photodetector further includes a Ge virtual substrate extending over the silicon-based substrate.

In some embodiments, the photodetector is operable at room temperature.

In some embodiments, the optoelectronic device is operable at a cryogenic temperature.

In some embodiments, the cryogenic temperature is equal or greater than about 77 K.

In some embodiments, each photoactive layer has a strain included in a range extending between about −2% to about +2%.

In accordance with another aspect, there is provided a method for manufacturing an optoelectronic device, including:
conditioning a reactor chamber to reach initial growth conditions;
forming a heterostructure on a substrate provided inside the reactor chamber, including:
   forming a first group IV alloy layer by exposing the substrate to the initial growth conditions; conditioning the reactor chamber to reach subsequent growth conditions; and
   forming at least one subsequent group IV alloy layer on the group IV alloy layer by exposing the first group IV alloy layer to the subsequent growth conditions, each group IV alloy layer in the heterostructure having a different or relatively similar Sn content one from another;
patterning the heterostructure and etching the heterostructure to expose a portion of the substrate;
patterning the heterostructure and etching the heterostructure to expose a portion of one of the first group W alloy layer and said at least one subsequent group IV alloy layer;
passivating the heterostructure;
etching contacts holes on the substrate through the heterostructure; and
depositing metal in the contact holes to form electrical contacts of the optoelectronic device.

In some embodiments, the group IV alloy layers includes at least two group IV elements selected from the group consisting of Si, Ge and Sn.

In some embodiments, the method further includes n-doping at least one of the group IV alloy layers with a group V element.

In some embodiments, the method further includes p-doping at least one of the group IV alloy layers with a group III element.

In some embodiments, the method further includes forming group IV alloy multi-quantum wells.

In some embodiments, the method further includes patterning the heterostructure to obtain an array of structures.

In some embodiments, the method further includes forming a metallic contact operatively connecting the heterostructure with the substrate.

In some embodiments, said forming the heterostructure includes forming at least one GeSn-based layer.

In some embodiments, said forming the heterostructure includes forming at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different thickness and lattice strain one from another.

In some embodiments, there is provided an optoelectronic device manufactured according to the method herein described.

In accordance with another aspect, there is provided a method for manufacturing a waveguide, including:
conditioning a reactor chamber to reach initial growth conditions;
forming a heterostructure on a substrate provided inside the reactor chamber, including:
   forming a first group IV alloy layer by exposing the substrate to the initial growth conditions;
   conditioning the reactor chamber to reach subsequent growth conditions; and
   forming at least one subsequent group IV alloy layer on the group IV alloy layer by exposing
   the first group IV alloy layer to the subsequent growth conditions, each group IV alloy layer in the heterostructure having a different or relatively similar Sn content one from another;
patterning the heterostructure and etching the heterostructure to expose a portion of the substrate;
patterning the heterostructure and etching the heterostructure to expose a portion of one of the first group W alloy layer and said at least one subsequent group IV alloy layer;

In some embodiments, the group IV alloy layers includes at least one group IV element selected from the group consisting of Si, Ge and Sn.

In some embodiments, the method further includes n-doping at least one of the group IV alloy layers with a group V element.

In some embodiments, the method further includes p-doping at least one of the group IV alloy layers with a group III element.

In some embodiments, the method further includes forming group IV alloy heterostructures.

In some embodiments, the method further includes forming group IV alloy multi-quantum wells.

In some embodiments, the substrate includes a virtual substrate layer extending over an original substrate layer, the method further including forming a waveguide by etching portions of the heterostructure and the virtual substrate.

In some embodiments, said etching the portions of the heterostructure and the virtual substrate includes isotropically etching the portions of the heterostructure and portions of the virtual substrate with Cl₂.

In some embodiments, said etching the portions of the heterostructure and the virtual substrate includes isotropically etching portions of the heterostructure and portions of the virtual substrate with CF₄.

In accordance with another aspect, there is provided a monolithic platform for on-chip emission and detection of infrared light, including:
a silicon-based substrate;
a light-emitting diode as herein described;
a photodetector as herein described; and
a waveguide connecting the light-emitting diode and the photodetector.

In some embodiments, the wavelength range extends from about 1 μm to about 8 μm.

In some embodiments, the monolithic platform is operable at room temperature.

In some embodiments, the optoelectronic device is operable at a cryogenic temperature.

In some embodiments, the cryogenic temperature is equal or greater than about 77 K.

In accordance with another aspect, there is provided a method for manufacturing a light-emitting diode, including:
conditioning a reactor chamber to reach initial growth conditions;
forming a heterostructure on a substrate provided inside the reactor chamber, including:
   forming a first group IV alloy layer by exposing the substrate to the initial growth conditions;
   conditioning the reactor chamber to reach subsequent growth conditions; and
   forming at least one subsequent group IV alloy layer on the group IV alloy layer by exposing the first group IV alloy layer to the subsequent growth conditions, each group IV alloy layer in the heterostructure having a different or relatively similar Sn content one from another;
releasing the heterostructure from the substrate to form a relaxed membrane; and
transferring the relaxed membrane on a host substrate.

In some embodiments, the group IV alloy layers includes at least two group IV elements selected from the group consisting of Si, Ge and Sn.

In some embodiments, the method further includes n-doping at least one of the group IV alloy layers.

In some embodiments, the method further includes p-doping at least one of the group IV alloy layers.

In some embodiments, the method further includes forming group IV alloy multi-quantum wells.

In some embodiments, the method further includes patterning the heterostructure to obtain an array of structures.

In some embodiments, the substrate includes a virtual substrate layer extending over an original substrate layer and wherein said releasing the heterostructure from the substrate includes etching portions of the heterostructure and the virtual substrate until the heterostructure collapses on the original substrate.

In some embodiments, said etching the portions of the heterostructure and the virtual substrate includes:
anisotropically etching the portions of the heterostructure and portions of the virtual substrate with Cl₂; and
isotropically etching remaining portions of the virtual substrate with CF₄.

In some embodiments, the method further includes forming a metallic contact operatively connecting the heterostructure with the substrate.

In some embodiments, said forming the heterostructure includes forming at least one GeSn-based layer.

In some embodiments, said forming the heterostructure includes forming at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, there is provided a light-emitting diode manufactured according to the method herein described.

In accordance with another aspect, there is provided a method for manufacturing a photodetector, including:
conditioning a reactor chamber to reach initial growth conditions;
forming a heterostructure on a substrate provided inside the reactor chamber, including:
   forming a first group IV alloy layer by exposing the substrate to the initial growth conditions;
   conditioning the reactor chamber to reach subsequent growth conditions; and
   forming at least one subsequent group IV alloy layer on the group IV alloy layer by exposing the first group IV alloy layer to the subsequent growth conditions, each group IV alloy layer in the heterostructure having a different or relatively similar Sn content one from another;
releasing the heterostructure from the substrate to form a relaxed membrane; and
transferring the relaxed membrane on a host substrate.

In some embodiments, the group IV alloy layers includes at least two group IV elements selected from the group consisting of Si, Ge and Sn.

In some embodiments, the method further includes n-doping at least one of the group IV alloy layers.

In some embodiments, the method further includes p-doping at least one of the group IV alloy layers.

In some embodiments, the method further includes forming group IV alloy multi-quantum wells.

In some embodiments, the method further includes patterning the heterostructure to obtain an array of structures.

In some embodiments, substrate includes a virtual substrate layer extending over an original substrate layer and wherein said releasing the heterostructure from the substrate includes etching portions of the heterostructure and the virtual substrate until the heterostructure collapses on the original substrate.

In some embodiments, said etching the portions of the heterostructure and the virtual substrate includes:
anisotropically etching the portions of the heterostructure and portions of the virtual substrate with Cl₂; and
isotropically etching remaining portions of the virtual substrate with CF₄.

In some embodiments, the method further includes forming a metallic contact operatively connecting the heterostructure with the substrate.

In some embodiments, said forming the heterostructure includes forming at least one GeSn-based layer.

In some embodiments, said forming the heterostructure includes forming at least two GeSn-based layers, each of said at least two GeSn-based layers having a different chemical composition one from another.

In some embodiments, the different chemical composition includes an Sn content.

In some embodiments, the Sn content of said at least two GeSn-based layers is included in a range extending between 1 at % and 25 at %.

In some embodiments, each of said at least two GeSn-based layers has a different lattice strain one from another.

In some embodiments, there is provided a photodetector manufactured according to the method herein described.

In accordance with another aspect, there is provided an optoelectronic device, including:
a silicon-based substrate;
a heterostructure at least partially extending over the silicon-based substrate, the heterostructure including one or more photoactive layers, each photoactive layer including at least one group IV element and being configured for absorbing short-wave infrared and mid-wave infrared radiation, the short-wave infrared and mid-wave infrared radiation being in a wavelength range extending from about 1 μm to about 8 μm; and
electrodes operatively connected to the heterostructure.

In some embodiments, said one or more photoactive layers includes a first layer made of Ge and a second layer made of GeSn, the second layer at least partially extending over the first layer.

In one implementation, there is provided a method for room-temperature detection of short-wave infrared and mid-wave infrared radiation at wavelengths exceeding 4 μm using a heterostructure including layers made of at least two group IV semiconductors grown on large silicon wafers.

In one implementation, there is provided a method for manufacturing a photodetector. The method may include a relatively precise engineering of the lattice parameter during the epitaxial growth of layers composed of at least two group IV elements at compositions and lattice strain yielding direct band gap semiconductors in the short-wave infrared and mid-wave infrared range. In some embodiments, the group IV elements are silicon, germanium and/or tin. In some embodiments, the semiconductors may have an indirect bandgap in the short-wave infrared and mid-wave infrared range.

In one implementation, there is provided a method for post-growth processing epitaxially grown layers or a heterostructure to further engineer the lattice strain and allow a significant relaxation to cover longer wavelengths in the short-wave infrared and mid-wave infrared range. Optoelectronic devices resulting from this method may include undoped and doped heterostructures, undoped and doped released nanomembranes, strained semiconductor(s), and relaxed semiconductor(s). The produced optoelectronic devices are compatible with silicon-based technologies and techniques. The ability to detect mid-wave infrared on a silicon platform creates a wealth of opportunities for sensing and imaging technologies. In some implementations, the compatibility with silicon will allow this novel family of mid-wave infrared optoelectronic devices to benefit from the complementary metal oxide semiconductor (CMOS) processing leading to a full exploitation of the current microelectronic and optoelectronic technologies.

In one implementation, there is provided a method for detaching photodetectors from an initial growth substrate and transferring the detached photodetectors onto a host substrate. In some embodiments, the host substrate may be transparent, flexible and/or curved substrate and/or a biological surface.

Other features will be better understood upon reading of embodiments thereof with reference to the appended drawings.

### BRIEF DESCRIPTION OF THE DRAWINGS

FIGS. 1(a-e). (a) Cross-sectional TEM image along the [110] zone axis of the GeSn 17/12/8 at. % (TL/ML/BL) multi-layer stacking grown on the Ge-VS/Si substrate. (b) XRD-RSM around the asymmetrical (224) reflection for the as-grown Ge_{0.83}Sn_{0.17} sample. (c) Schematics of the microdisk fabrication process. (d) SEM image of the Ge_{0.83}Sn_{0.17} micro-disks (37.5° tilting angle). (e) Raman spectra for Ge_{0.83}Sn_{0.17} acquired on the as-grown (blue curve) and on the central portion of the microdisk (red curve).

FIG. 2. Schematic depicting the GeSn under-etch-induced relaxation and flake transfer onto semi-insulating substrate.

FIGS. 3(a-e). Optical images of as-grown GeSn heterostructure (a), as-transferred GeSn membrane (b). (c) and (d) show the corresponding Raman maps recorded using Ge-Ge mode; (e) Individual Ge—Ge spectra measured for as-grown heterostructure (black curve), partially detached membrane (red curve), and fully detached membrane (blue curve).

FIGS. 4. Optical image of as-transferred membrane along with Ge—Ge Raman mode map, the strain distribution and the calculated bandgap energy map.

FIG. 5 Scanning electron microscopy image of as-transferred GeSn membranes (top). Optical image of a photodetector fabricated using transferred GeSn membrane (bottom). Inset: A close-up image showing the membrane underneath the contact fingers.

FIGS. 6(a-b). (a) IV curves for the total current and the photocurrent of the photodetector. (b) The spectral responsivity for the relaxed transferred PD compared to another PD made of as grown GeSn.

FIG. 7. Performance of a variety of GeSn short-wave infrared and mid-wave infrared photodetectors fabricated using layers at different Sn content and lattice strain.

FIGS. 8(a-b). (a) PL spectra and absorption coefficient squared (A2) at 300 K for the as-grown Ge_{0.83}Sn_{0.17} and (b) micro-disk samples. In the A² curves, the intercept of the straight dashed line extrapolates the energy of the optical transition(s).

FIGS. 9(a-d). (a-b) SEM images the Ge_{0.83}Sn_{0.17} micro-disk arrays (37.5° tilting angle) showing few micro-disks that are detached from the Ge-VS and redeposited in a different location. (c) Raman maps indicating the complete GeSn and Ge-VS removal in between the micro-disks and (d) the peak position across the individual micro-disks.

FIG. 10. Schematics of the optical setup use for transmission measurements. A supercontinuum laser has been used as a white light source with emission up to 4.1 μm or has been replaced by the internal glow bar of the FTIR system for measurements further in the infrared. The emission of the source was then coupled through the interferometer and focused onto the sample which was placed at the entrance of a gold-coated integrating sphere. The light was collected from the integrating sphere through a baffled port and focused onto an HgCdTe-detector. Background measurements have been performed directly before each transmission measurement and the total transmission was determined as Tₜₒₜ=Tₘₑₐₛ/T_{background}.

FIGS. 11(a-b). Schematics of all reflections taken into account for the determination of the total transmission Tₜₒₜ. Where in (a) only the reflections at the outside of the samples are taken into account (see equation S4) and in (b) the additional reflection on the germanium-silicon interface (see equation S5). In this figure tₓ is a transmission through a respective medium, Rₓ is a reflection between two media and R*ₓ and T*ₓ are the effective reflection and transmission through a layer taking into account multiple reflections.

FIGS. 12(a-b). (a) Relation between the measured transmission Tₜₒₜ and the transmission due to non-absorbed light tₜₒₜ and the relation between Tₜₒₜ and (b) the absorbance (equation S3) of the measured GeSn samples. In these graphs no reflections at interfaces are taken into account (black line), only reflections at the air-sample interfaces are taken into account (solid blue line, equation S4) and air-sample interfaces and the Ge—Si interface inside the sample are taken into account (orange dashed line and see equation S5). All graphs are calculated using refractive indices of nₛᵢ=3.4 and n_{Ge}=4.2.

FIGS. 13(a-c). (a) The transmittance and absorbance of the as-grown Ge_{0.83}Sn_{0.17} sample, measured using a supercontinuum source. (b) The transmittance and absorbance of the Ge_{0.83}Sn_{0.17} micro-disks, measured using a glow bar. (c) The transmittance and absorbance of the as-grown Ge_{0.863}Sn_{0.137} sample, measured using a supercontinuum source. The A² curve is a derived function from transmission data according to the procedure described in the supporting information.

FIGS. 14(a-b). Extrapolated 8-band k⋅p band gap value at 300 K based on the temperature dependence of the PL emission (shown in FIGS. 4 and 5) for strained and relaxed (a) Ge_{0.83}Sn_{0.17} and (b) Ge_{0.88}Sn_{0.12}.

FIGS. 15(a-c). (a) PL spectra acquired using excitation power densities from 6.9 W/cm² to 5.4 kW/cm². Plot of the (b) integrated PL intensity and (c) emission energy as a function of the excitation power density.

FIG. 16. Mass spectrum extracted from the APT measurements of Ge_{0.83}Sn_{0.17}.

FIG. 17. Micrograph of a light-emitting diode.

FIG. 18. Signal intensity compared for EL and PL from a fabricated LED device and PL from an as-grown sample.

FIG. 19. Micrograph of a GeSn PIN photodetector.

FIG. 20(a-c). (a) Spectral responsivity for GeSn PIN device at RT and 78 K along with RT PL for the as-grown sample; (b) detectivity comparison of the Ex-InGaAs at RT with GeSn device at RT and 78 K; and (c) IV for dark current for various devices diameters at 78 K compared to Ex-InGaAs at RT.

### DETAILED DESCRIPTION

In the following description, similar features in the drawings have been given similar reference numerals. In order to not unduly encumber the figures, some elements may not be indicated on some figures if they were already mentioned in preceding figures. It should also be understood herein that the elements of the drawings are not necessarily drawn to scale and that the emphasis is instead being placed upon clearly illustrating the elements and structures of the present embodiments.

The terms “a”, “an” and “one” are defined herein to mean “at least one”, that is, these terms do not exclude a plural number of items, unless stated otherwise.

Terms such as “substantially”, “generally” and “about”, that modify a value, condition or characteristic of a feature of an exemplary embodiment, should be understood to mean that the value, condition or characteristic is defined within tolerances that are acceptable for the proper operation of this exemplary embodiment for its intended application.

Unless stated otherwise, the terms “connected” and “coupled”, and derivatives and variants thereof, refer herein to any structural or functional connection or coupling, either direct or indirect, between two or more elements. For example, the connection or coupling between the elements may be acoustical, mechanical, optical, electrical, logical, or any combination thereof.

In the present description, the terms “light” and “optical”, and variants and derivatives thereof, are used to refer to radiation in any appropriate region of the electromagnetic spectrum. The terms “light” and “optical” are therefore not limited to visible light, but can also include, without being limited to, the infrared region of the electromagnetic spectrum. For example, in some implementations, the present techniques can be used with electromagnetic signals having wavelengths ranging from about 700 nm to about 30 μm (referred to as the “infrared portion of the electromagnetic spectrum”), and more particularly from about 1 μm to about 8 μm (referred to as the “short-wave infrared and mid-wave infrared portion of the electromagnetic spectrum”). However, this range is provided for illustrative purposes only and some implementations of the present techniques may operate outside this range. Also, the skilled person will appreciate that the definition of the ultraviolet, visible and infrared ranges in terms of spectral ranges, as well as the dividing lines between them, may vary depending on the technical field or the definitions under consideration, and are not meant to limit the scope of applications of the present techniques.

The expression “heterostructure” will be used throughout the description and refers to a structure including at layers with different composition, lattice strain and/or electronic properties. In some implementations, the heterostructure may include at least two group IV alloy-based layers.

The expression “device” refers to a component or an assembly associated with a functionality. For example, an “optoelectronic device” is a device that can accomplish a specific functionality involving the use or manipulation of both charge carriers and photons (e.g., lasers, light emitting diodes, photodetectors, solar cells, sensors and imagers, and others). Many other types of devices exist, such as, and without being limitative ultrafast transistors, quantum information devices, spintronics devices, energy conversion devices, sensors and imagers, and hybrid photonics-electronics devices.

The expression “strained lattice” will be used when the lattice parameter in at least one crystallographic direction is different than the value at equilibrium. In this context, the lattice is said to be “stretched” when the lattice parameter is larger than the value at equilibrium, and the lattice is said to be “compressed” when the lattice parameter is smaller than the value at equilibrium. As such, the expression “strain” will be used to reflect a relative change in lattice parameter with respect to its equilibrium value. It is to be noted that the expressions “lattice constant” and “lattice parameter”, which will be used interchangeably, refer to the equilibrium interatomic distance along a specific crystallographic direction in a crystalline material. A layer or a heterostructure is said to be relaxed when its lattice parameters undergo a transition from strained state to reach values close or equal to those at the equilibrium. This transition may occur during growth or by post-growth release.

The group IV elements are the elements of column IV of the periodic table, e.g., C, Si, Ge, Sn and Pb and their stable isotopes.

The term “alloy” refers to a material or a composition including at least two different elements. For example, and without being limitative, an alloy could include two, three or four different elements. In some implementations, the alloys may include at least two group IV elements.

The term “p-type doping” refers to the incorporation of an impurity in the growing layer to create an excess of positive charges known as holes. The term “n-type doping” refers to the incorporation of an impurity in the growing layer to create an excess of negative charges known as electrons. The term “intrinsic doping (i)” refers to the case where a semiconductor layer has no excess negative or positive charges.

The terms “p-n junction” or “n-p junction” refer to two successive layers, wherein one layer is p-type doped and the other one is n-type doped. The terms “p-i-n junction” or “n-i-p junction” refer to three successive layers, wherein one layer is p-type doped, one is intrinsic, and one is n-type doped.

Theoretical context

Free-space optical communications, infrared harvesting, biological and chemical sensing, and imaging technologies would strongly benefit from the availability of scalable, cost-effective, and silicon- (Si-) compatible short-wave infrared and mid-wave infrared optoelectronic devices. With this perspective, Sn-containing group IV semiconductors, such as, for example GeSn grown on Si wafers have recently been the subject of extensive investigations, as exemplified in references 1 to 5. At the core of these expended efforts is the ability to harness the relatively efficient direct band gap emission from these emerging semiconductors, which can be achieved at a Sn content around 10 at. % in fully relaxed layers. It is, however, noteworthy that this critical content is significantly above the about 1 at. % equilibrium solubility of Sn in Ge, which calls for a precise control of the growth kinetics to prevent phase separation and avoid Sn segregation and material degradation. Moreover, the epitaxial growth of GeSn is typically achieved on Si wafers using a Ge interlayer — commonly known as a “Ge virtual substrate” (which will be referred to as “Ge-VS” or “virtual substrate” in the present description), resulting in inherently compressively strained GeSn layer(s) [see references 6 and 7], thus increasing the Sn content threshold for the indirect-to-direct band gap crossover, and, as a result, the associated optical emission is shifted to higher energies [see references 8 to 10]. In some cases, this behavior is also associated with a broadening of the emission peak and a decrease in its intensity as a result of the degradation in the material quality at high Sn contents. Moreover, the strain in the GeSn epitaxial layers was found to affect the incorporation of Sn throughout the growth, which can lead to graded composition as the layers grow thicker [see references 6,7].

Among the strategies to circumvent the GeSn growth hurdles, lattice parameter engineering using multi-layer and step-graded growth has been shown to be effective in controlling the Sn content and its uniformity. This process was exploited in recent studies demonstrating room-temperature optical emission and detection down to 0.36 eV (approximately 3.4 μm wavelength), see for example reference 4, as well as optically-pumped lasing operating between about 3.1 μm to about 3.4 μm at temperatures in the range of about 180 K to about 270 K (see for example references 11 to 13). In addition to lattice parameter engineering during the growth, post-growth control and manipulation of strain has also been utilized to extend the emission range as longer wavelengths can be achieved through relaxation and tensile strain engineering. Notwithstanding the contributions from these recent studies, the current GeSn-based photodetector technology is still limited to a range below 4 um and with a very limited performance at room temperature.

The technology and its advantages will become more apparent from the detailed description and examples that follow, which describe the various embodiments of the technology.

Short-wave infrared and mid-wave infrared optoelectronic device and related methods

In accordance with one aspect, there is provided an optoelectronic device having an operation range reaching and exceeding 4 μm and operable at room temperature or at a cryogenic temperature. Optoelectronic devices such as described herein may include a silicon-based substrate and a heterostructure extending over at least a portion of the silicon-based substrate. The heterostructure may include a stack of coextending photoactive layers and each photoactive layer may include one or two group IV elements. In some implementations, the photoactive layers are configured for absorbing and/or emitting short-wave infrared and mid-wave infrared radiation. In some implementations, the short-wave infrared and mid-wave infrared radiation is in a wavelength range extending from 1 μm to-8 μm. In some embodiments, the group IV elements are selected from the group consisting of: Si, Ge and Sn. In some embodiments, the wavelength range extends from about 2 μm to about 8 μm. In some embodiments, the wavelength range extends from about 1 μm to about 1.7 μm. In some embodiments, the wavelength range extends from about 1 μm to about 2.7 μm. In some embodiments, the wavelength range extends from about 1 μm to about 3.3 μm. In some embodiments, the wavelength range extends from about 1 μm to about 3.5 μm. In some embodiments, the wavelength range extends from about 1 μm to about 4.7 μm.

In accordance with another aspect, there is provided a method for manufacturing an optoelectronic device. The method includes conditioning a reactor chamber to reach initial growth conditions. The method includes forming a heterostructure on a substrate provided inside the reactor chamber, which may include forming a first GeSn layer by exposing the substrate to the initial growth conditions, conditioning the reactor chamber to reach subsequent growth conditions and forming at least one subsequent GeSn layer on the GeSn layer by exposing the first GeSn layer to the subsequent growth conditions, each GeSn layer in the heterostructure having a different Sn content one from another. The method includes releasing the heterostructure from the substrate to form a relaxed membrane and transferring the relaxed membrane on a host substrate. In some embodiments, the method includes patterning the heterostructure to obtain an array of structures. In one nonlimitative example, the array of structures is an array of micro-disks. In some embodiments, the substrate includes a virtual substrate layer extending over an original substrate layer and the step of releasing the heterostructure from the substrate includes etching portions of the heterostructure and the virtual substrate until the heterostructure collapses on the original substrate. In some embodiments, the step of etching the portions of the heterostructure and the virtual substrate includes anisotropically etching the portions of the heterostructure and portions of the virtual substrate with Cl₂, and anisotropically etching remaining portions of the virtual substrate with CF₄. In some embodiments, the method includes forming a metallic contact operatively connecting the heterostructure with the substrate.

In some implementations, the optoelectronic device is a GeSn-based photodetector on a Si substrate. For example, the photodetector may include (Si)GeSn-based heterostructure(s), which may either be undoped or doped, and forming p-i-n junctions.

In some implementations, the optoelectronic device is a GeSn-based light-emitting diode on a Si substrate.

Optoelectronic devices as described herein are examples of group IV integrated optoelectronic or photonic devices operating in the short-wave infrared and mid-wave infrared range that may serve as platforms for scalable, compact, and silicon-compatible technologies. In some implementations, the photodetectors may be incorporated in sensors and imaging devices.

In accordance with another aspect, there is also provided a method for manufacturing such optoelectronic devices and photodetectors. The method may include strain-engineering the heterostructure, either during the epitaxial growth or after the epitaxial growth, i.e., during the processing of the optoelectronic device or photodetector. In some implementations, the method may include releasing the heterostructure from the substrate to form membrane photodetectors. In some implementations, the method may include transferring the membrane photodetectors on a host substrate, i.e., a substrate different than the substrate on which the heterostructure has been grown onto. Examples of host substrates include, but are not limited to oxidized surfaces, transparent substrates, biological surfaces, and/or flexible substrates. In some implementations, the method may include independently engineering the strain and the composition of the heterostructure. In some implementations, the method may be used for manufacturing photodetectors on silicon, the photodetectors having a wavelength cut-off exceeding 4 μm at room temperature. The method as described herein is a silicon-compatible technology and may be associated with a wealth of opportunities for relatively low-cost and relatively high-performance short-wave infrared and mid-wave infrared sensing and imaging applications.

In accordance with another aspect, there is provided an optoelectronic device including a silicon-based substrate, a heterostructure at least partially extending over the silicon-based substrate and electrodes operatively connected to the heterostructure. The heterostructure includes a stack of coextending photoactive layers, each photoactive layer including at least two group IV elements and being configured for absorbing short-wave infrared and mid-wave infrared radiation, the short-wave infrared and mid-wave infrared radiation being in a wavelength range extending from about 1 μm to about 8 μm.

In some embodiments, said at least two group IV elements are selected from the group consisting of: Si, Ge and Sn. In some embodiments, the wavelength range extends from about 2 μm to about 8 μm. In some embodiments, the wavelength range extends from about 1 μm to about 1.7 μm. In some embodiments, the wavelength range extends from about 1 μm to about 2.7 μm. In some embodiments, the wavelength range extends from about 1 μm to about 3.3 μm. In some embodiments, the wavelength range extends from about 1 μm to about 3.5 μm. In some embodiments, the stack of coextending photoactive layers includes at least one GeSn-based layer. In some embodiments, the stack of coextending photoactive layers includes at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different lattice strain one from another. In some embodiments, the optoelectronic device, further includes a Ge virtual substrate extending over the silicon-based substrate. In some embodiments, the optoelectronic device is operable at room temperature. In some embodiments, the optoelectronic device is operable at a cryogenic temperature. In some embodiments, the cryogenic temperature is equal or greater than about 77 K. In some embodiments, each photoactive layer has a strain included in a range extending between about −2% to about +2%.

In accordance with another aspect, there is provided a photodetector including a silicon-based substrate, a heterostructure at least partially extending over the silicon-based substrate and electrodes operatively connected to the heterostructure. The heterostructure includes a stack of coextending photoactive layers, each photoactive layer including at least two group IV elements and being configured for detecting short-wave infrared and mid-wave infrared radiation, the short-wave infrared and mid-wave infrared radiation being in a wavelength range extending from about 1 82 m to about 8 μm.

In some embodiments, said at least two group IV elements are selected from the group consisting of: Si, Ge and Sn. In some embodiments, the wavelength range extends from about 2 μm to about 8 μm. In some embodiments, the wavelength range extends from about 1 μm to about 1.7 μm. In some embodiments, the wavelength range extends from about 1 μm to about 2.7 μm. In some embodiments, the wavelength range extends from about 1 μm to about 3.3 μm. In some embodiments, the wavelength range extends from about 1 μm to about 3.5 μm. In some embodiments, the stack of coextending photoactive layers includes at least one GeSn-based layer. In some embodiments, the stack of coextending photoactive layers includes at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different lattice strain one from another. In some embodiments, the photodetector, further includes a Ge virtual substrate extending over the silicon-based substrate. In some embodiments, the photodetector is operable at room temperature. In some embodiments, the optoelectronic device is operable at a cryogenic temperature. In some embodiments, the cryogenic temperature is equal or greater than about 77 K. In some embodiments, each photoactive layer has a strain included in a range extending between about −2% to about +2%.

In accordance with another aspect, there is provided a light-emitting diode, including a silicon-based substrate, a heterostructure at least partially extending over the silicon-based substrate and electrodes operatively connected to the heterostructure. The heterostructure includes a stack of coextending photoactive layers, each photoactive layer including at least two group IV elements and being configured for emitting short-wave infrared and mid-wave infrared radiation, the short-wave infrared and mid-wave infrared radiation being in a wavelength range extending from about 1 μm to about 8 μm.

In some embodiments, said at least two group IV elements are selected from the group consisting of: Si, Ge and Sn. In some embodiments, wavelength range extends from about 2 μm to about 8 μm. In some embodiments, the wavelength range extends from about 1 μm to about 1.7 μm. In some embodiments, the wavelength range extends from about 1 μm to about 2.7 μm. In some embodiments, the wavelength range extends from about 1 μm to about 3.3 μm. In some embodiments, the wavelength range extends from about 1 μm to about 3.5 μm. In some embodiments, the stack of coextending photoactive layers includes at least one GeSn-based layer. In some embodiments, the stack of coextending photoactive layers includes at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different lattice strain one from another. In some embodiments, the light-emitting diode further includes a Ge virtual substrate extending over the silicon-based substrate. In some embodiments, the light-emitting diode is operable at room temperature. In some embodiments, the optoelectronic device is operable at a cryogenic temperature. In some embodiments, the cryogenic temperature is equal or greater than about 77 K. In some embodiments, each photoactive layer has a strain included in a range extending between about −2% to about +2%.

In accordance with another aspect, there is provided an optoelectronic platform, including a silicon-based substrate, a heterostructure at least partially extending over the silicon-based substrate and electrodes operatively connected to the heterostructure. The heterostructure includes a stack of coextending photoactive layers, each photoactive layer including at least two group IV elements and being configured to perform at least one of emitting short-wave infrared and mid-wave infrared radiation and detecting the short-wave infrared and mid-wave infrared radiation. The short-wave infrared and mid-wave infrared radiation is in a wavelength range extending from about 1 μm to about 8 μm.

In some embodiments, said at least two group IV elements are selected from the group consisting of: Si, Ge and Sn. In some embodiments, the wavelength range extends from about 2 μm to about 8 μm. In some embodiments, the wavelength range extends from about 2 μm to about 2.8 μm. In some embodiments, the wavelength range extends from about 1 μm to about 1.7 μm. In some embodiments, the wavelength range extends from about 1 μm to about 2.7 μm. In some embodiments, the wavelength range extends from about 1 μm to about 3.3 μm. In some embodiments, the wavelength range extends from about 1 μm to about 3.5 μm. In some embodiments, the stack of coextending photoactive layers includes at least one GeSn-based layer. In some embodiments, the stack of coextending photoactive layers includes at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different lattice strain one from another. In some embodiments, the optoelectronic platform further includes a Ge virtual substrate extending over the silicon-based substrate. In some embodiments, the optoelectronic platform is operable at room temperature. In some embodiments, the optoelectronic device is operable at a cryogenic temperature. In some embodiments, the cryogenic temperature is equal or greater than about 77 K. In some embodiments, each photoactive layer has a strain included in a range extending between about −2% to about +2%.

In accordance with another aspect, there is provided a method for manufacturing an optoelectronic device. The method includes conditioning a reactor chamber to reach initial growth conditions and forming a heterostructure on a substrate provided inside the reactor chamber. The step of forming the heterostructure includes forming a first group IV alloy layer by exposing the substrate to the initial growth conditions; conditioning the reactor chamber to reach subsequent growth conditions; and forming at least one subsequent group IV alloy layer on the group IV alloy layer by exposing the first group IV alloy layer to the subsequent growth conditions, each group IV alloy layer in the heterostructure having a different or relatively similar Sn content one from another. The method further includes releasing the heterostructure from the substrate to form a relaxed membrane and transferring the relaxed membrane on a host substrate.

In some embodiments, the group IV alloy layers includes at least two group IV elements selected from the group consisting of Si, Ge and Sn. In some embodiments, the method further includes n-doping at least one of the group IV alloy layers. In some embodiments, the method further includes p-doping at least one of the group IV alloy layers. In some embodiments, the method further includes forming group IV alloy multi-quantum wells. In some embodiments, the method further includes patterning the heterostructure to obtain an array of structures. In some embodiments, the substrate includes a virtual substrate layer extending over an original substrate layer and wherein said releasing the heterostructure from the substrate includes etching portions of the heterostructure and the virtual substrate until the heterostructure collapses on the original substrate. In some embodiments, said etching the portions of the heterostructure and the virtual substrate includes: anisotropically etching the portions of the heterostructure and portions of the virtual substrate with Cl₂; and isotropically etching remaining portions of the virtual substrate with CF₄. In some embodiments, the method further includes forming a metallic contact operatively connecting the heterostructure with the substrate. In some embodiments, said forming the heterostructure includes forming at least one GeSn-based layers. In some embodiments, said forming the heterostructure includes forming at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different lattice strain one from another. In some embodiments, there is provided an optoelectronic device manufactured according to the method herein described.

In accordance with another aspect, there is provided a method for manufacturing an optoelectronic device. The method includes forming a heterostructure on a substrate provided inside a reactor chamber. The step of forming the heterostructure includes forming a first group IV alloy layer by exposing the substrate to initial growth conditions; and forming at least one subsequent group IV alloy layer on the group IV alloy layer. The method further includes varying a precursor concentration inside the reactor chamber while forming the heterostructure to obtain subsequent growth conditions, such that each group IV alloy layer in the heterostructure has a different Sn content one from another upon exposure to the subsequent growth conditions.

In some embodiments, the group IV alloy layers includes at least two group IV elements selected from the group consisting of Si, Ge and Sn. In some embodiments, the method further includes n-doping at least one of the group IV alloy layers. In some embodiments, the method further includes p-doping at least one of the group IV alloy layers. In some embodiments, the method further includes forming group IV alloy multi-quantum wells. In some embodiments, the method further includes patterning the heterostructure to obtain an array of structures. In some embodiments, the method further includes forming a metallic contact operatively connecting the heterostructure with the substrate. In some embodiments, said forming the heterostructure includes forming at least one GeSn-based layers. In some embodiments, said forming the heterostructure includes forming at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different lattice strain one from another. In some embodiments, there is provided an optoelectronic device manufactured according to the method herein described.

In accordance with another aspect, there is provided a light-emitting diode. The light-emitting diode includes a silicon-based substrate, a heterostructure at least partially extending over the silicon-based substrate and electrodes operatively connected to the heterostructure. The heterostructure includes a stack of coextending photoactive layers, each photoactive layer including at least two group IV elements and being configured for emitting short-wave infrared and mid-wave infrared radiation, the short-wave infrared and mid-wave infrared radiation being in a wavelength range extending from about 2 μm to about 2.8 μm.

In some embodiments, the light-emitting diode has a diameter of about 40 μm. In some embodiments, the stack of coextending photoactive layers includes at least one GeSn-based layer. In some embodiments, the stack of coextending photoactive layers includes at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different lattice strain one from another. In some embodiments, each of said at least two GeSn-based layers has a different thickness one from another. In some embodiments, the light-emitting diode further includes a Ge virtual substrate extending over the silicon-based substrate. In some embodiments, the light-emitting diode is operable at room temperature. In some embodiments, the optoelectronic device is operable at a cryogenic temperature. In some embodiments, the cryogenic temperature is equal or greater than about 77 K. In some embodiments, each photoactive layer has a strain included in a range extending between about −2% to about +2%.

In accordance with another aspect, there is provided a photodetector. The photodetector includes a silicon-based substrate, a heterostructure at least partially extending over the silicon-based substrate and electrodes operatively connected to the heterostructure. The heterostructure includes a stack of coextending photoactive layers, each photoactive layer including at least two group IV elements and being configured for detecting short-wave infrared and mid-wave infrared radiation, the short-wave infrared and mid-wave infrared radiation being in a wavelength range extending from about 1 μm to about 2.6 μm.

In some embodiments, the photodetector has a diameter included in a range extending from about 20 μm to about 160 μm. In some embodiments, the stack of coextending photoactive layers includes at least one GeSn-based layer. In some embodiments, the stack of coextending photoactive layers includes at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different lattice strain one from another. In some embodiments, the photodetector further includes a Ge virtual substrate extending over the silicon-based substrate. In some embodiments, the photodetector is operable at room temperature. In some embodiments, the optoelectronic device is operable at a cryogenic temperature. In some embodiments, the cryogenic temperature is equal or greater than about 77 K. In some embodiments, each photoactive layer has a strain included in a range extending between about −2% to about +2%.

In accordance with another aspect, there is provided a method for manufacturing an optoelectronic device. The method includes conditioning a reactor chamber to reach initial growth conditions and forming a heterostructure on a substrate provided inside the reactor chamber. The step of forming the heterostructure includes forming a first group IV alloy layer by exposing the substrate to the initial growth conditions; conditioning the reactor chamber to reach subsequent growth conditions; and forming at least one subsequent group IV alloy layer on the group IV alloy layer by exposing the first group IV alloy layer to the subsequent growth conditions, each group IV alloy layer in the heterostructure having a different or relatively similar Sn content one from another. The method further includes patterning the heterostructure and etching the heterostructure to expose a portion of the substrate, patterning the heterostructure and etching the heterostructure to expose a portion of one of the first group IV alloy layer and said at least one subsequent group IV alloy layer, passivating the heterostructure, etching contacts holes on the substrate through the heterostructure and depositing metal in the contact holes to form electrical contacts of the optoelectronic device.

In some embodiments, the group IV alloy layers includes at least two group IV elements selected from the group consisting of Si, Ge and Sn. In some embodiments, the method further includes n-doping at least one of the group IV alloy layers with a group V element. In some embodiments, the method further includes p-doping at least one of the group IV alloy layers with a group III element. In some embodiments, the method further includes forming group IV alloy multi-quantum wells. In some embodiments, the method further includes patterning the heterostructure to obtain an array of structures. In some embodiments, the method further includes forming a metallic contact operatively connecting the heterostructure with the substrate. In some embodiments, said forming the heterostructure includes forming at least one GeSn-based layer. In some embodiments, said forming the heterostructure includes forming at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different thickness and lattice strain one from another. In some embodiments, there is provided an optoelectronic device manufactured according to the method herein described.

In accordance with another aspect, there is provided a method for manufacturing a waveguide. The method includes conditioning a reactor chamber to reach initial growth conditions and forming a heterostructure on a substrate provided inside the reactor chamber. The step of forming the heterostructure includes forming a first group IV alloy layer by exposing the substrate to the initial growth conditions; conditioning the reactor chamber to reach subsequent growth conditions; and forming at least one subsequent group IV alloy layer on the group IV alloy layer by exposing the first group IV alloy layer to the subsequent growth conditions, each group IV alloy layer in the heterostructure having a different or relatively similar Sn content one from another. The method further includes patterning the heterostructure and etching the heterostructure to expose a portion of the substrate and patterning the heterostructure and etching the heterostructure to expose a portion of one of the first group IV alloy layer and said at least one subsequent group IV alloy layer.

In some embodiments, the group IV alloy layers includes at least one group IV element selected from the group consisting of Si, Ge and Sn. In some embodiments, the method further includes n-doping at least one of the group IV alloy layers with a group V element. In some embodiments, the method further includes p-doping at least one of the group IV alloy layers with a group III element. In some embodiments, the method further includes forming group IV alloy heterostructures. In some embodiments, the method further includes forming group IV alloy multi-quantum wells. In some embodiments, the substrate includes a virtual substrate layer extending over an original substrate layer, the method further including forming a waveguide by etching portions of the heterostructure and the virtual substrate. In some embodiments, said etching the portions of the heterostructure and the virtual substrate includes isotropically etching the portions of the heterostructure and portions of the virtual substrate with Cl₂. In some embodiments, said etching the portions of the heterostructure and the virtual substrate includes isotropically etching portions of the heterostructure and portions of the virtual substrate with CF₄.

In accordance with another aspect, there is provided a monolithic platform for on-chip emission and detection of infrared light. The monolithic platform includes a silicon-based substrate, a light-emitting diode as herein described, a photodetector as herein described and a waveguide connecting the light-emitting diode and the photodetector.

In some embodiments, the wavelength range extends from about 1 μm to about 8 μm. In some embodiments, the monolithic platform is operable at room temperature. In some embodiments, the optoelectronic device is operable at a cryogenic temperature. In some embodiments, the cryogenic temperature is equal or greater than about 77 K.

In accordance with another aspect, there is provided a method for manufacturing a light-emitting diode. The method includes conditioning a reactor chamber to reach initial growth conditions and forming a heterostructure on a substrate provided inside the reactor chamber. The step of forming the heterostructure includes forming a first group IV alloy layer by exposing the substrate to the initial growth conditions; conditioning the reactor chamber to reach subsequent growth conditions; and forming at least one subsequent group IV alloy layer on the group IV alloy layer by exposing the first group IV alloy layer to the subsequent growth conditions, each group IV alloy layer in the heterostructure having a different or relatively similar Sn content one from another. The method further includes releasing the heterostructure from the substrate to form a relaxed membrane and transferring the relaxed membrane on a host substrate.

In some embodiments, the group IV alloy layers includes at least two group IV elements selected from the group consisting of Si, Ge and Sn. In some embodiments, the method further includes n-doping at least one of the group IV alloy layers. In some embodiments, the method further includes p-doping at least one of the group IV alloy layers. In some embodiments, the method further includes forming group IV alloy multi-quantum wells. In some embodiments, the method further includes patterning the heterostructure to obtain an array of structures. In some embodiments, the substrate includes a virtual substrate layer extending over an original substrate layer and wherein said releasing the heterostructure from the substrate includes etching portions of the heterostructure and the virtual substrate until the heterostructure collapses on the original substrate. In some embodiments, said etching the portions of the heterostructure and the virtual substrate includes anisotropically etching the portions of the heterostructure and portions of the virtual substrate with Cl₂; and isotropically etching remaining portions of the virtual substrate with CF₄. In some embodiments, the method further includes forming a metallic contact operatively connecting the heterostructure with the substrate. In some embodiments, said forming the heterostructure includes forming at least one GeSn-based layer. In some embodiments, said forming the heterostructure includes forming at least two GeSn-based layers, each of said at least two GeSn-based layers having a different chemical composition one from another. In some embodiments, the different chemical composition includes an Sn content.

In some embodiments, the Sn content of said at least two GeSn-based layers is included in a range extending between 1 at % and 25 at %. In some embodiments, each of said at least two GeSn-based layers has a different lattice strain one from another. In some embodiments, there is provided a light-emitting diode manufactured according to the method herein described.

In accordance with another aspect, there is provided a method for manufacturing a photodetector. The method includes conditioning a reactor chamber to reach initial growth conditions. The method also includes forming a heterostructure on a substrate provided inside the reactor chamber. The step of forming the heterostructure includes forming a first group IV alloy layer by exposing the substrate to the initial growth conditions; conditioning the reactor chamber to reach subsequent growth conditions; and forming at least one subsequent group IV alloy layer on the group IV alloy layer by exposing the first group IV alloy layer to the subsequent growth conditions, each group IV alloy layer in the heterostructure having a different or relatively similar Sn content one from another. The method further includes releasing the heterostructure from the substrate to form a relaxed membrane and transferring the relaxed membrane on a host substrate.

In some embodiments, the group IV alloy layers includes at least two group IV elements selected from the group consisting of Si, Ge and Sn. In some embodiments, the method further includes n-doping at least one of the group IV alloy layers. In some embodiments, the method further includes p-doping at least one of the group IV alloy layers. In some embodiments, the method further includes forming group IV alloy multi-quantum wells. In some embodiments, the method further includes patterning the heterostructure to obtain an array of structures. In some embodiments, substrate includes a virtual substrate layer extending over an original substrate layer and wherein said releasing the heterostructure from the substrate includes etching portions of the heterostructure and the virtual substrate until the heterostructure collapses on the original substrate. In some embodiments, said etching the portions of the heterostructure and the virtual substrate includes: anisotropically etching the portions of the heterostructure and portions of the virtual substrate with Cl₂; and isotropically etching remaining portions of the virtual substrate with CF₄. In some embodiments, the method further includes forming a metallic contact operatively connecting the heterostructure with the substrate. In some embodiments, said forming the heterostructure includes forming at least one GeSn-based layer. In some embodiments, said forming the heterostructure includes forming at least two GeSn-based layers, each of said at least two GeSn-based layers having a different chemical composition one from another. In some embodiments, the different chemical composition includes an Sn content. In some embodiments, the Sn content of said at least two GeSn-based layers is included in a range extending between 1 at % and 25 at %. In some embodiments, each of said at least two GeSn-based layers has a different lattice strain one from another. In some embodiments, there is provided a photodetector manufactured according to the method herein described.

In accordance with another aspect, there is provided an optoelectronic device, including a silicon-based substrate, a heterostructure and electrodes. The heterostructure at least partially extends over the silicon-based substrate, and includes one or more photoactive layers, each photoactive layer including at least one group IV element and being configured for absorbing short-wave infrared and mid-wave infrared radiation, the short-wave infrared and mid-wave infrared radiation being in a wavelength range extending from about 1 μm to about 8 μm. The electrodes are operatively connected to the heterostructure.

In some embodiments, said one or more photoactive layers includes a first layer made of Ge and a second layer made of GeSn, the second layer at least partially extending over the first layer.

Examples and results

The section below provides examples of embodiments of a mid-wave infrared optoelectronic device and related methods, as well as examples of results related to embodiments of the mid-wave infrared optoelectronic device and related methods. The following section should not be interpreted as being limitative and serves an illustrative purpose only.

Besides the ability to engineer optoelectronic devices, the availability of high quality GeSn layers also provides a rich playground to tune the electronic and optical properties by exploiting various physical parameters. For instance, lattice strain and composition are always interrelated in epitaxial GeSn layers and play a key role in shaping the device performance. In some implementations, there is provided a method to tune these two parameters during growth or after growth. The epitaxial growth is performed on silicon wafers in a low-pressure chemical vapor deposition (CVD) reactor using ultra-pure H₂ carrier gas, and 10% monogermane (GeH₄) and tin-tetrachloride (SnCl₄) precursors, similar to a recently developed growth protocol, which is described in the U.S. Provisional Patent Application No.: 62/856,500, the content of which is incorporated by reference in its entirety. N-type and p-type doping is achieved using AsH₃ and B2H₆ precursors, respectively.

Optimization of GeSn material properties

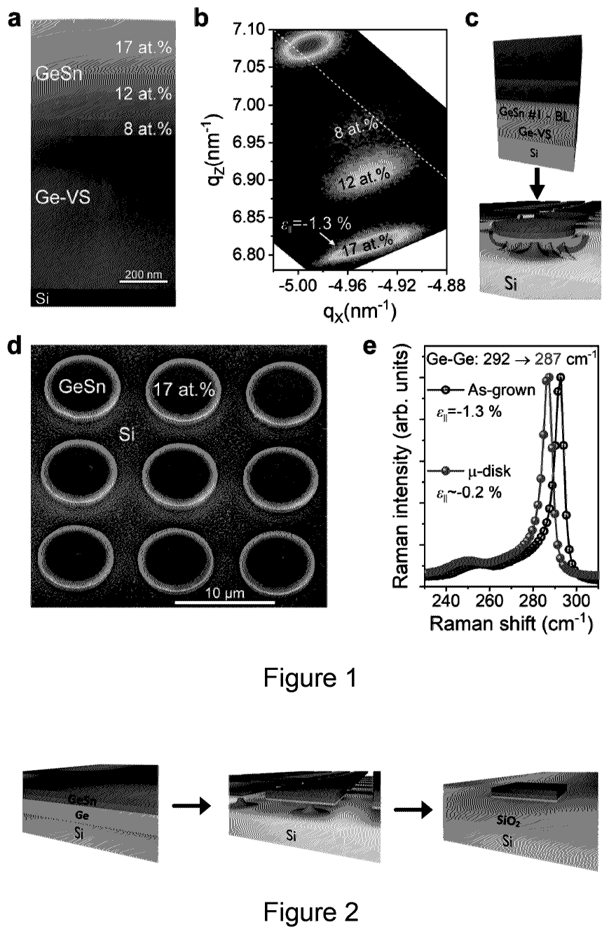

The method for manufacturing the GeSn photodetectors allows independently engineering the Sn content and the lattice strain, which enables a relatively precise control of the optoelectronic properties of the GeSn device structures (i.e., the heterostructures). FIGS. 1(a-e) display an example of as-grown GeSn layers with a Sn content reaching 17%. In FIG. 1(a), a cross-sectional TEM image along the [110] zone axis of the GeSn is shown. In this illustrated embodiment, the content of Sn in the GeSn heterostructure is 17/12/8 at. %, for the top layer (TL), the middle layer (ML) and the bottom layer (BL), respectively, and the GeSn heterostructure is grown on s Ge-VS/Si substrate. The composition of each layer is estimated from Reciprocal Space Mapping (RSM) around the asymmetrical (224) X-ray diffraction (XRD) peak, as illustrated in FIG. 1(b). The data indicate that the TL is under an in-plane biaxial compressive strain ε_{(∥)}=−1.3%.

The method may include a step of etching the Ge-VS to significantly relax this residual strain and releasing the GeSn layers. In some implementations, the grown layers may be patterned and etched to form 2.5×2.5 mm² arrays of GeSn micro-disks, as illustrated in FIG. 1(c). In some implementations, the anisotropic reactive ion etching (RIE) of the sidewalls of the micro-disks was achieved using Cl₂, followed by selective etching of the Ge-VS substrate using CF₄ in RIE.

The scanning electron microscope (SEM) image in FIG. 1(d) exhibits atypical array of micro-disks having a diameter of about 7 μm and a pitch of about 10 μm. The apparent change in the contrast of the outer rim (about 1 μm in width) may be due to a partial over-etching of the 17 at. % TL during the CF₄ processing, resulting from a non-uniform wetting of the negative resist. The CF₄ etching time is typically selected to completely release the GeSn micro-disks until they collapse on the Si wafer. It is to be noted that a small residual thickness of the Ge-VS layer may be visible on the Si substrate under the micro-disk after the fabrication process, see the Appendix A—Supporting Information. It is to be noted that the presence of the small residual thickness of the Ge-VS layer does not substantially affect the strain in the GeSn micro-disks because they are detached from the substrate. Raman measurements were performed on the micro-disk arrays to evaluate the residual strain in the GeSn TL. It is to be noted that Raman spectra are recorded from the TL without any contribution form the underlaying layers as the penetration depth of the 633 nm excitation laser (<30 nm) is significantly smaller than the TL thickness (about 160 nm). FIG. 1(e) displays Raman spectra acquired at the center of a single GeSn micro-disk (red curve). As a reference, the Raman spectrum of the as-grown Ge_{0.83}Sn_{0.17} layer is also shown (blue curve). The Ge—Ge LO mode of the as-grown layer is centered at about 292 cm⁻¹, whereas the same mode shifts down to about 287 cm⁻¹ upon under-etching. The observed about 5 cm⁻¹ shift corresponds to a strain relaxation from the as-grown value of about −1.3% down to about −0.2% in the GeSn micro-disks. It will be noted that the Raman spectra associated with the area between the GeSn micro-disks only show the Si—Si LO mode at about 520 cm⁻¹ from the substrate (see the Appendix A—Supporting Information), indicating that the Ge-VS was completely etched leading to the observed strain relaxation. It will be noted that the measured residual strain (−0.2%) in the TL even after the complete release of the micro-disks is expected because the GeSn stack includes, in the illustrated embodiment, three layers with a variable composition. This post-etching strain analysis is consistent with our systematic studies decoupling Sn content and strain effects on GeSn Raman vibrational modes.

A relatively accurate theoretical framework to evaluate the band structure of these multilayers is highly coveted to elucidate or better understand the interplay between the composition, strain, and structural parameters for the investigated GeSn heterostructures. For instance, in order to be able to quantitatively interpret any spectroscopic related transitions, the band gaps in each layer of the GeSn heterostructure (i.e., the TL, ML and BL) need to be estimated as a function of their respective strain and Sn content. The 8-band k⋅p model together with envelope function approximation (EFA) may be used to that end (see reference 17) The strain implementation is based on the Bir-Pikus formalism (see reference 18). Additionally, the model solid theory was adopted to estimate the conduction and valence band offset profiles of various high symmetry bands (see references 19 and 20). It will be noted that the linear interpolation formulae are inaccurate to estimate the band gaps of binary compounds due to significant bowing effects in the L and Γ Brillouin zone directions. To circumvent this limitation, the bowing parameters (at 0 K) b₆₄ =1.94 and b_{L}=1.23 were used. The obtained diagrams demonstrate that the electron and holes diffuse into the upmost 17 at. % layer, as a result of the band offset with the 12 at. % ML being higher than 30 meV for both electrons and heavy holes (HH). Besides, the TL layer strain relaxation (from about −1.3% to about −0.2%) induces an increase of E_{g}^{L-r}(=E_{g}^{L}−E_{g}⁶⁴ ) by about 83 meV, which may enhance band to band recombination. Furthermore, the LH-HH splitting is reduced by about 80 meV in the TL layer. The valence (conduction) band offset between the ML and TL are reduced (increased) by about 14 meV (about 56 meV) due to strain relaxation. For instance, Low et al. have shown using empirical pseudopotential method that the band gaps for the unstrained Ge_{0.83}Sn_{0.17} at γ and L brillouin directions were equal to 0.42 eV and 0.45 eV which compares fairly well with the current k⋅p parametrization which gives 0.421 eV and 0.525 eV, respectively (see reference 21). Additionally, based on Gupta's work (see reference 8), the as-grown ML layer (12% at. Sn, −0.54% compressive strain) is predicted to have a direct band gap of 0.54 eV, which in perfect agreement with our current k⋅p model where the ML direct gap transition is 0.574 eV. These calculated results are used in design and implementation of devices discussed below.

Photodetector device processing and optimization

As described below, the strain and composition of the GeSn heterostructures may be independently engineered, which may enable more flexibility to tune the optical properties of GeSn. Photodetectors or similar devices may be developed using this material system.

A variety of photodetectors using the as-grown GeSn heterostructures directly on silicon substrates, as well as released and transferred GeSn heterostructures have been produced. The latter allows for an additional strain relaxation.

Some aspects of the method for manufacturing a GeSn photodetector will now be described.

In some implementations, the GeSn photodetector fabrication started by spin coating a photoresist mask for chlorine etch using ICP Oxford Instruments PlasmaLab System 100 etcher.

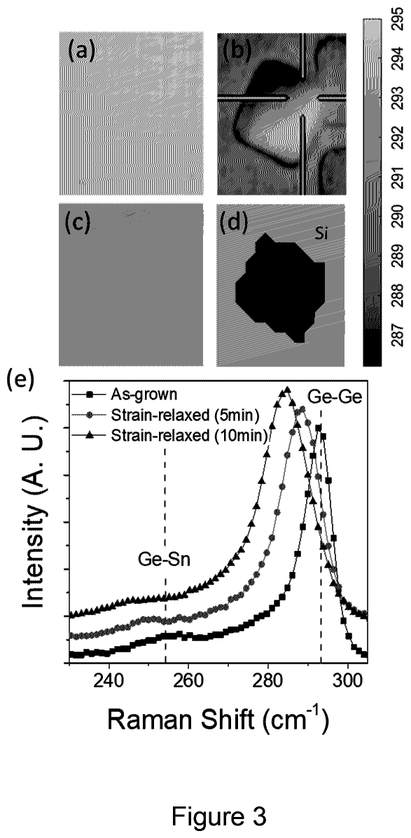

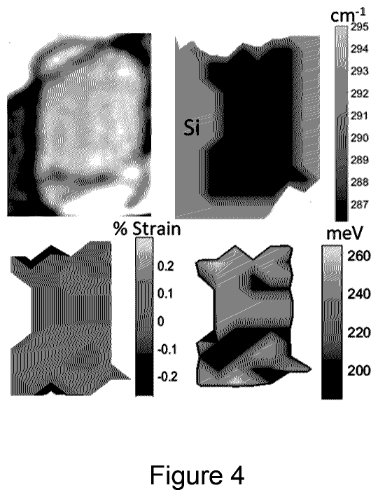

In some implementations, the etching may be done by flowing Cl₂/N₂/O₂ at 40/10/4 sccm at 30° C., 20 mTorr pressure and 100 W RF power for 3 minutes, which is generally sufficient to etch all of the GeSn/Ge-VS layers reaching to the Si substrate (i.e., exposing the Si substrate). Following SEM inspection, the photoresist may be stripped using O₂ plasma asher at 400 sccm and 500 W at room temperature for 2 minutes. To under-etch and release the GeSn layers, the Ge-VS layer may be etched using fluorine-based etching, which has a relatively high selectivity in etching Ge and preserving GeSn of rich Sn content. This fluorine etch may be made by plasma asher flowing CF₄ at 200 sccm and 200 W for 5 minutes. This fluorine etch may completely release the GeSn layer(s), thereby leaving 20 μm X 20 μm flakes that may be subsequently transferred onto semiinsulating SiO2/p++−Si substrate with 90 nm of SiO₂. A transfer station from Graphene-hq company may be used to transfer the GeSn flakes onto the semi-insulating substrate which has gold grid and align marks to help aligning the contacts to these flakes later on. Polycarbonate (PC, Sigma Aldrich, 6% dissolved in chloroform) atop PDMS may be used to help picking up the flakes that have been completely under-etched. The PC with the flakes may then be released from the PDMS and dropped off onto the semi-insulating substrate and heated at 150° C. to increase the contact area of PC with the SiO₂ and melt the PC onto the substrate. The PC residue may be cleaned by soaking the sample in chloroform for 10 minutes, leaving the GeSn Flakes on top of the substrate. HCl:DI water 1:4 may be used for cleaning of the transferred flakes to reduce the GeSn native oxide and this may be followed by spin coating MAMA/PMMA two layer resist for EBL patterning. The two-layer resist may be made to get MMA resist thickness that is enough to lift-off a 300 nm thick metal and to get a decent undercut resist profile, which helps in metal lift-off without the need for ultrasonication which could easily damage these devices. In some implementations, the method may include providing a thick metal contact to ensure the electrical connection despite the mesa formed by the GeSn thick flake edge, and its curved surface profile formed by the strain relaxation. EBL may be used to pattern the photodetector contacts on the transferred flakes aligning them in reference to the already existing gold grid on the semi-insulating substrate. The contacts may be deposited using e-beam evaporation for Ti/Au (30 nm/270 nm). Lift-off may be done using remover 1165 while soaking at 70° C. for one hour. FIG. 2 exhibits illustrates the lift-off process which has been described and FIG. 3 shows an optical image of a typical as-transferred GeSn heterostructure on the host substrate (sometimes referred to as a “foreign substrate”). The figure also exhibits Raman spectra confirming the strain relaxation upon transfer of the membrane. FIG. 4 demonstrate the effect of strain relaxation on band gap energy in a single membrane.

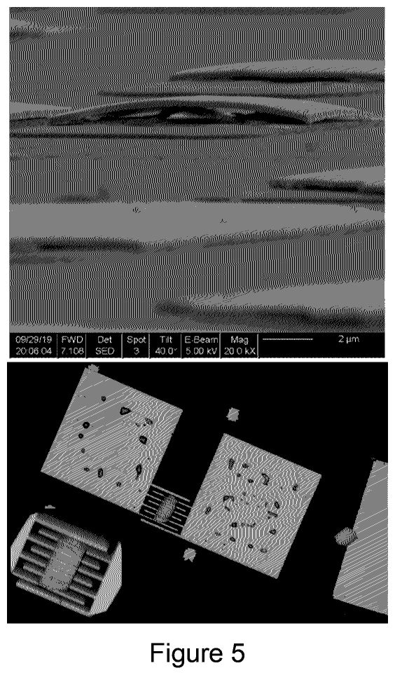

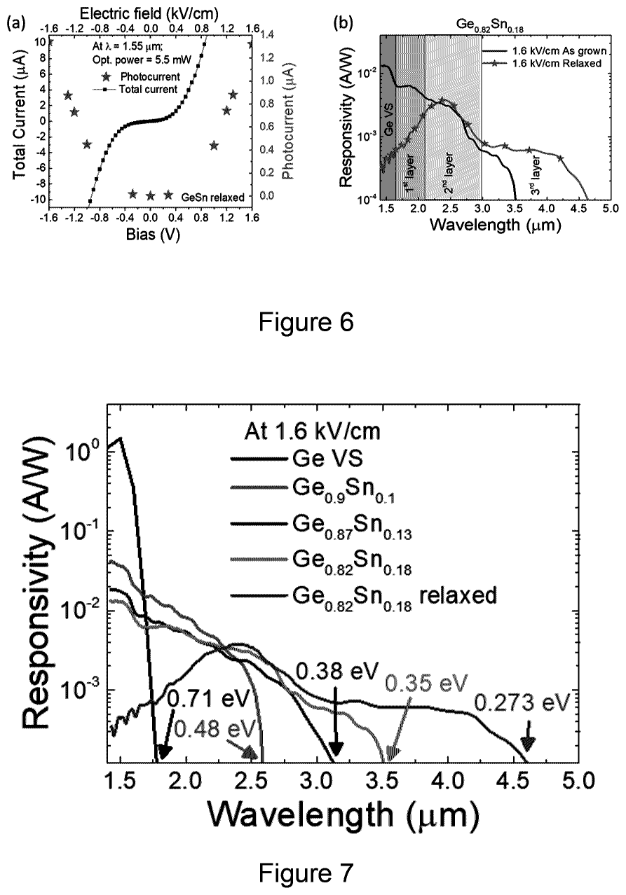

FIG. 5 demonstrate a typical photodetector fabricated using a transferred membrane. The IV measurements may be done using a Keithley 4200a parameter analyzer connected to a probe station. As shown in FIG. 6(a), the W curves of these devices depicted low dark current with Schottky behavior which most likely occurred as a result of fluorine-based etching of these flakes. The photocurrent was measured at 1.55 μm wavelength and it shows a nonlinear IV curve as the bias increases. Moreover, the spectral responsivity may be measured using Broker Vertex 70 FTIR spectrometer. In this scenario, the mid-wave infrared light source of the FTIR is incident on the GeSn device and the electrical signal may be measured using a Zurich Instruments lock in amplifier locked to the frequency of a chopper in the light path of the mid-wave infrared light source. The lock in signal may be fed to the FTIR electronics to eventually get the photocurrent as function of wavelength. Knowing the power profile of the mid-wave infrared light source, the spectral responsivity of the PD can be calculated, as shown in FIG. 6b. It will be noted that the under-etch-induced strain relaxation of the GeSn layers has significantly increased the cut-off wavelength from 3.5 μm (for as grown GeSn PD) to 4.55 μm. It will be noted that the wavelength cut-off of these photodetectors may be tuned by adjusting the strain and Sn content. In this regard, FIG. 7 displays the performance of various photodetectors fabricated using different GeSn layers at different Sn content and lattice strain. FIG. 7 shows that the wavelength cut-off may be controlled from about 1.7 μm to about 4.5 μm, using the techniques which have been herein described.

Advantageously, the optoelectronic devices and method herein described may share a significant portion of the existing low-cost processing infrastructure being currently used for Si-based technologies. This compatibility with silicon processing may be useful for fabricating short-wave infrared and mid-wave infrared devices at significantly lower prices than current III-V and II-VI technology allows. It is estimated that GeSn short-wave infrared and mid-wave infrared chips may be two to three orders of magnitude cheaper than current III-V and II-VI chips. The low material cost provided by the GeSn compatibility with silicon processing also paves the way for improved and/or better performance, as large area devices may be fabricated leading to higher resolution focal plan arrays. Moreover, the monolithic integration on silicon allows the combination of both electronic and photonic devices on the same platform, which may enable new opportunities for a variety of scalable and cost-effective technologies, which include, but are not limited to monolithic imaging sensors, readout integrated circuit (ROIC), optical transceivers (e.g., intra-chip and inter-chip), gyroscopes, magnetometers, accelerometers, spectrum analyzers, LIDAR and many others.

Additionally, transferring GeSn membranes on various host substrates may bring in new capabilities to integrated mid-wave infrared photodetectors on different, flexible or curved substrates or biological surfaces. This hetero-integration may be useful, for example and without being limitative, for wearable, flexible, curved sensors and/or imaging systems.

The compatibility of the technology described herein with silicon may drive opportunities for this novel family of mid-wave infrared devices to benefit from the complementary metal oxide semiconductor (CMOS) processing, which may lead to a more complete exploitation of the current microelectronic and optoelectronic technologies, which may be associated, for example and without being limitative to a production in a high-volume Si wafer fab with repeatability, uniformity, and cost-effectiveness, a standard design flow making photonics design very similar to CMOS design with a library of elementary devices allowing the manipulation of light in the same way as electrical signals, and managing supply chain from wafers to final product including on-wafer testing for electrical and optical functionalities, manufacturing of large focal plane arrays (FPAs), thus enabling high performances for high-resolution and high-sensitivity short-wave infrared and mid-wave infrared imaging and sensing technologies at low cost

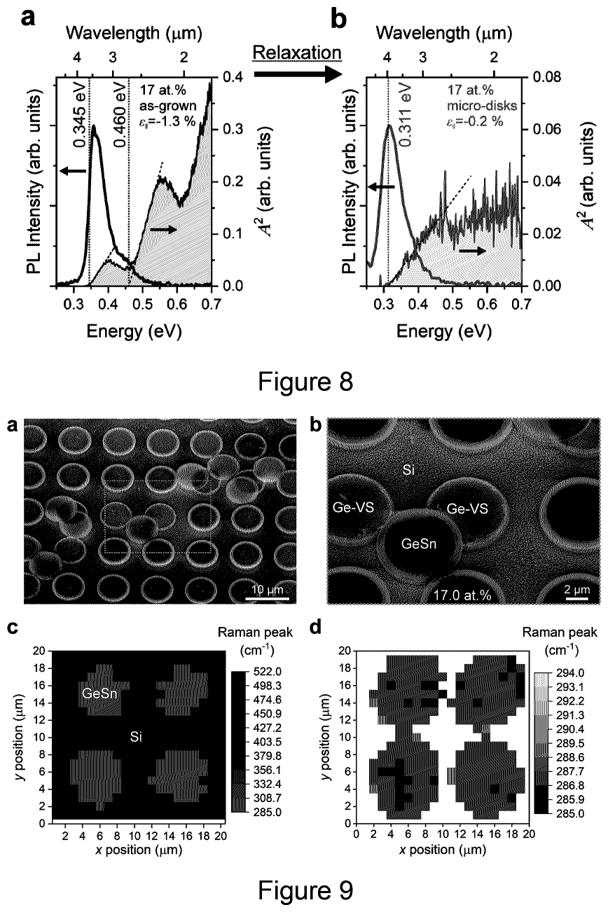

To experimentally investigate the effect of strain relaxation on the optical properties of GeSn, room-temperature PL and transmission measurements were performed on both as-grown Ge_{0.83}Sn_{0.17} heterostructures and micro-disk arrays etched from the same sample using a Fourier transform infrared (FTIR) spectrometer. The PL spectra are displayed in FIGS. 8(a-b). In the as-grown Ge_{0.83}Sn_{0.17} a main peak centered at about 0.362±0.005 eV (i.e., about 3.4 μm wavelength) is observed with a full-width at half maximum (FWHM) of about 40 to 50 meV. A low intensity emission peak at about 0.43 eV is also visible, which may be related either to the optical recombination in the underlying 12 at. % ML or to optical transitions involving LH instead of HH. However, the optical emission in this sample mainly originates from the 160 nm-thick 17 at. % TL, as recently demonstrated by changing the penetration depth of the incoming light using lasers emitting at different wavelengths (see reference 4). In the GeSn micro-disks, the optical emission is shifted down to about 0.315±0.005 eV (FWHM of about 60-70 meV) compared to the as-grown sample, thus covering a broader range in the MIR up to about 4.0 μm to about 4.5 μm, as illustrated in FIG. 8(b). The measured about 45 meV (i.e., about 0.5 μm in wavelength) shift in the optical emission is induced by the strain relaxation from the as-grown value of about -1.3% to about -0.2% in the GeSn micro-disks. The observed increase in the FWHM of the emission peak in the GeSn micro-disks may be related to the RIE under-etching process, where small fluctuations in strain between different GeSn micro-disks may be present, thus leading to a broader emission peak. Alternatively, the splitting of the HH and LH bands, induced by the compressive strain in the as-grown layer, vanishes almost completely in the GeSn micro-disks, due to the significant relaxation. Following the calculation results shown in FIG. 4, a residual about 20 meV splitting between the HH and LH is expected, which substantially corresponds with the additional broadening of the micro-disks compared to the strained layer, where the FWHM is determined only by the contribution of the LH. These results suggest that not only accurate control of a homogeneous composition is required to enhance the quality of the PL signal, but also a full and homogeneous relaxation of the residual strain in the GeSn heterostructures or layers forming the same, to both control the emission wavelength and the line-width. It will be noted that the room-temperature PL peak of the Ge_{0.83}Sn_{0.17} micro-disks at 0.31 eV is in very good agreement with the optical emission in strain-free Ge_{0.81}Sn_{0.19} nanowires, where the PL emission is observed at 0.30 eV at room-temperature (see reference 14).

The optical emission from the Ge_{0.83}Sn_{0.17} samples may be correlated with the transmission measurements performed at 300 K. To provide a precise evaluation of the transmission data and to be able to determine the band gaps of the individual layers we define the absorbance as: A=Σᵢαᵢ·dᵢ, where αᵢ and dᵢ are the absorption coefficient and thickness of layer I, where the summation runs over all layers in the GeSn heterostructure. The surface reflections between the different layers were taken into account and the spectra have been baseline-corrected to compensate for free-carrier absorption (see references 22 and 23), as discussed in more detail in the Appendix A—Supporting Information. The obtained A² curves are plotted in FIGS. 8(a-b), together with their respective PL spectra. In a direct band gap semiconductor, the absorption coefficient a scales as the square root of the energy and scales proportional to A, therefore A² shows a linear behavior with energy where the band gap is given by the energy-axis crossing. The A² spectrum shows a band gap for the as-grown 17 at. % (ε_{∥}=−1.3%) TL of about 0.345±0.005 eV, which lies on the rising edge of the corresponding PL signal centered at about 0.362 eV as expected. Similarly, the band gap of the 12 at. % Sn (ε_{∥}=−0.5%) ML is found to be about 0.46±0.02 eV, which is in very good agreement with the 8-band k⋅p estimated band gap of about 0.44 eV. Additionally, this value is in close agreement with the estimated 0.45 eV in Ge_{0.875}Sn_{0.125} (ε_{∥}=−0.3%), using reflection measurements provided in reference 14. The band gaps found for the MLs suffer from a small red-shift because their energy-axis crossing is also partially determined by the absorption in the TL, which is accounted for with a larger error margin. It will however be noted that the obtained values for both samples agree closely, which supports the robustness of the method being used. The third onset above 0.6 eV is a result from both the 8 at. % BL as well as the thick Ge-VS layer, where transitions to the indirect L-minimum dominate.

In the Ge_{0.83}Sn_{0.17} micro-disks, only one absorption onset at about 0.311±0.005 eV is visible. The found band gap in this case lies at the center of the PL instead of on the rising slope. This relatively very small discrepancy may be a result of small fluctuations in the strain relaxation where PL is more likely to probe the lowest band gap material and the absorption measurement averages all contributions. Nonetheless, the measured 35±7 meV shift with respect to the as-grown (strained) Ge_{0.83}Sn_{0.17} is in excellent agreement with the about 45 meV shift estimated from the PL measurements. This result supports that the band gap shift is induced by the strain relaxation from the as-grown value of −1.3% to −0.2% in the micro-disks. Surprisingly, a rather flat A2 curve is observed above 0.45 eV, without the presence of additional absorption edges at higher energy associated with the 12-8 at. % Sn layers. Even though the prolongated CF₄ under-etching of the Ge-VS may have induced a partial etching of the lower Sn content layers, the complete absence of additional absorption peaks can hardly be justified based on these considerations. Since a significantly lower signal-to-noise ratio in the transmission measurements was obtained when measuring the micro-disks (because of a reduced absorption volume and a fraction of transmitted light not interacting with the micro-disks), this may prevent the detection transition edges at higher energies. It will be noted that another possible effect (thought less likely) may be the enhanced absorption upon strain relaxation resulting from a higher oscillator strength for the direct band gap transition in a strain-free Ge_{0.83}Sn_{0.17} layer, thus hindering additional signal from the layers underneath.

Their individual effect on the optical emission of GeSn may be decoupled and elucidated by performing systematic studies on the optical emission of strained and relaxed GeSn in the 4 K to 300 K range. It has been found that the room temperature (RT) optical emission wavelength may be extended above 4 μm upon significant post-growth relaxation of the compressive strain (−1.3%) in under-etched Ge_{0.83}Sn_{0.17.} By cooling down to about 4 K, the single emission peak is preserved in both strained and relaxed layers, which is indicative of the direct band gap emission across the entire temperature range. Thermally activated non-radiative recombination channels were found to have a negligible effect on the emission of Ge_{0.83}Sn_{0.17} and no additional impurity-related emission were observed upon post-growth relaxation. Interestingly, in relaxed Ge_{0.83}Sn_{0.17}, the reduction in PL intensity to about 15% of its initial value is observed when the temperature increases from 4 K to 300 K. Similar qualitative and quantitative behavior was found in lower Sn content layers, e.g., Ge_{0.863}Sn_{0.137}, with an initial in-plane compressive strain of about −0.4% and RT PL emission at about 0.38 eV (about 3.3 μm). 8 ×8k⋅p band structure calculations confirm the recorded behavior of the PL emission peak energy upon relaxation of the epitaxial strain.

The technology described in the present disclosure may be useful in many different fields of application such as, for example and without being limitative, defence technologies, chemical sensing, covert crowd-screening, intelligence gathering, security screening systems, explosive detection, surveillance, anti-counterfeiting measures, medical diagnostics tools, environmental pollution monitoring, detection of trace gases, autonomous and semi-autonomous vehicles and aircrafts, night vision, electronic board inspection, solar cell inspection, produce inspection; identifying and sorting, biomedical research; biochemical sensing and wearable sensing and imaging technologies.

Several alternative embodiments and examples have been described and illustrated herein. The embodiments described above are intended to be exemplary only. A person skilled in the art would appreciate the features of the individual embodiments, and the possible combinations and variations of the components. A person skilled in the art would further appreciate that any of the embodiments could be provided in any combination with the other embodiments disclosed herein. The present examples and embodiments, therefore, are to be considered in all respects as illustrative and not restrictive. Accordingly, while specific embodiments have been illustrated and described, numerous modifications come to mind without significantly departing from the scope defined in the appended claims.

References for the detailed description

(1) Wirths, S.; Geiger, R.; von den Driesch, N.; Mussler, G.; Stoica, T.; Mantl, S.; Ikonic, Z.; Luysberg, M.; Chiussi, S.; Hartmann, J. M.; et al. Lasing in Direct-Band gap GeSn Alloy Grown on Si. Nat. Photonics 2015, 9 (2), 88-92. https://doi.org/10.1038/nphoton.2014.321.

(2) Margetis, J.; Al-Kabi, S.; Du, W.; Dou, W.; Zhou, Y.; Pham, T.; Grant, P.; Ghetmiri, S.; Mosleh, A.; Li, B.; et al. Si-Based GeSn Lasers with Wavelength Coverage of 2-3 Mm and Operating Temperatures up to 180 K. ACS Photonics 2018, 5 (3), 827-833. https://doi.org/10.1021/acsphotonics.7b00938.

(3) Reboud, V.; Gassenq, A.; Pauc, N.; Aubin, J.; Milord, L.; Thai, Q. M.; Bertrand, M.; Guilloy, K.; Rouchon, D.; Rothman, J.; et al. Optically Pumped GeSn Micro-Disks with 16% Sn Lasing at 3.1 μ m up to 180 K. Appl. Phys. Lett. 2017, 111 (9), 092101. https://doi.org/10.1063/1.5000353.

(4) Assali, S.; Nicolas, J.; Mukherjee, S.; Dijkstra, A.; Moutanabbir, O. Atomically Uniform Sn-Rich GeSn Semiconductors with 3.0-3.5 Mm Room-Temperature Optical Emission. Appl. Phys. Lett. 2018, 112 (25), 251903. https://doi.org/10.1063/1.5038644.

(5) Attiaoui, A.; Wirth, S.; Blanchard-Dionne, A.-P.; Meunier, M.; Hartmann, J. M.; Buca, D.; Moutanabbir, O. Extreme IR Absorption in Group IV-SiGeSn Core-Shell Nanowires. J. Appl. Phys. 2018, 123 (22), 223102. https://doi.org/10.1063/1.5021393.

(6) Margetis, J.; Yu, S.-Q.; Bhargava, N.; Li, B.; Du, W.; Tolle, J. Strain Engineering in Epitaxial Ge1-xSnx: A Path towards Low-Defect and High Sn-Content Layers. Semicond. Sci. Technol. 2017, 32 (12), 124006. https://doi.org/10.1088/1361-6641/aa7fc7.

(7) Assali, S.; Nicolas, J.; Moutanabbir, O. Enhanced Sn Incorporation in GeSn Epitaxial Semiconductors via Strain Relaxation. J. Appl. Phys. 2019, 125 (2), 025304. https://doi.org/10.1063/1.5050273.

(8) Gupta, S.; Magyari-Köpe, B.; Nishi, Y.; Saraswat, K. C. Achieving Direct Band Gap in Germanium through Integration of Sn Alloying and External Strain. J. Appl. Phys. 2013, 113 (7). https://doi.org/10.1063/1.4792649.

(9) Attiaoui, A.; Moutanabbir, O. Indirect-to-Direct Band Gap Transition in Relaxed and Strained Ge1-x-ySixSny Ternary Alloys. J. Appl. Phys. 2014, 116 (6), 063712. https://doi.org/10.1063/1.4889926.

(10) Polak, M. P.; Scharoch, P.; Kudrawiec, R. The Electronic Band Structure of Ge 1-x Sn x in the Full Composition Range: Indirect, Direct, and Inverted Gaps Regimes, Band Offsets, and the Burstein-Moss Effect. J. Phys. D. Appl. Phys. 2017, 50 (19), 195103. https://doi.org/10.1088/1361-6463/aa67bf.

(11) Stange, D.; von den Driesch, N.; Zabel, T.; Armand-Pilon, F.; Rainko, D.; Marzban, B.; Zaumseil, P.; Hartmann, J.-M.; Ikonic, Z.; Capellini, G.; et al. GeSn/SiGeSn Heterostructure and Multi Quantum Well Lasers. ACS Photonics 2018, 5 (11), 4628-4636. https://doi.org/10.1021/acsphotonics.8b01116.

(12) Zhou, Y.; Dou, W.; Du, W.; Ojo, S.; Tran, H.; Ghetmiri, S. A.; Liu, J.; Sun, G.; Soref, R.; Margetis, J.; et al. Optically Pumped GeSn Lasers Operating at 270 K with Broad Waveguide Structures on Si. ACS Photonics 2019, 6 (6), 1434-1441. https://doi.org/10.1021/acsphotonics.9b00030.

(13) Chrétien, J.; Pauc, N.; Armand Pilon, F.; Bertrand, M.; Thai, Q.-M.; Casiez, L.; Bernier, N.; Dansas, H.; Gergaud, P.; Delamadeleine, E.; et al. GeSn Lasers Covering a Wide Wavelength Range Thanks to Uniaxial Tensile Strain. ACS Photonics 2019, 6 (10), 2462-2469. https://doi.org/10.1021/acsphotonics.9b00712.

(14) Atalla, M. R., Assali, S., Attiaoui, A., Lemieux-Leduc, C., Kumar, A., Abdi, S. and Moutanabbir, O., 2020. All-Group IV Transferable Membrane Mid-Infrared Photodetectors. Advanced Functional Materials, p.200632.

(15) Assali, S., Dijkstra, A., Attiaoui, A., Bouthillier, E., Haverkort, J.E.M. and Moutanabbir, O., 2021. Midinfrared Emission and Absorption in Strained and Relaxed Direct-Band-Gap Ge 1-x Sn x Semiconductors. Physical Review Applied, 15(2), p.024031.

APPENDIX A—Supporting information

Structural characterization of the Ge_{0.83}Sn_{0.17} micro-disks

In FIGS. 8(a-b), there are illustrated SEM images of the Ge_{0.83}Sn_{0.17} micro-disk arrays (37.5° tilting angle) showing few micro-disks that are detached from the Ge-VS and redeposited in a different location. FIGS. 8(c-d) shows Raman maps indicating the complete GeSn and Ge-VS removal in between the micro-disks and the peak position across the individual micro-disks, respectively.

Description of transmission setup

In FIG. 9, there is illustrated the optical setup used for transmission measurements. A supercontinuum laser has been used as a white light source with emission up to 4.1 μm or has been replaced by the internal glow bar of the FTIR system for measurements further in the infrared. The emission of the source was then coupled through the interferometer and focused onto the sample which was placed at the entrance of a gold-coated integrating sphere. The light was collected from the integrating sphere through a baffled port and focused onto an HgCdTe-detector. Background measurements have been performed directly before each transmission measurement and the total transmission was determined as Tₜₒₜ=Tₘₑₐₛ/T_{background}. The further analysis of the data is described in Supporting Information S3.

Determination of the Absorptivity from transmission measurements

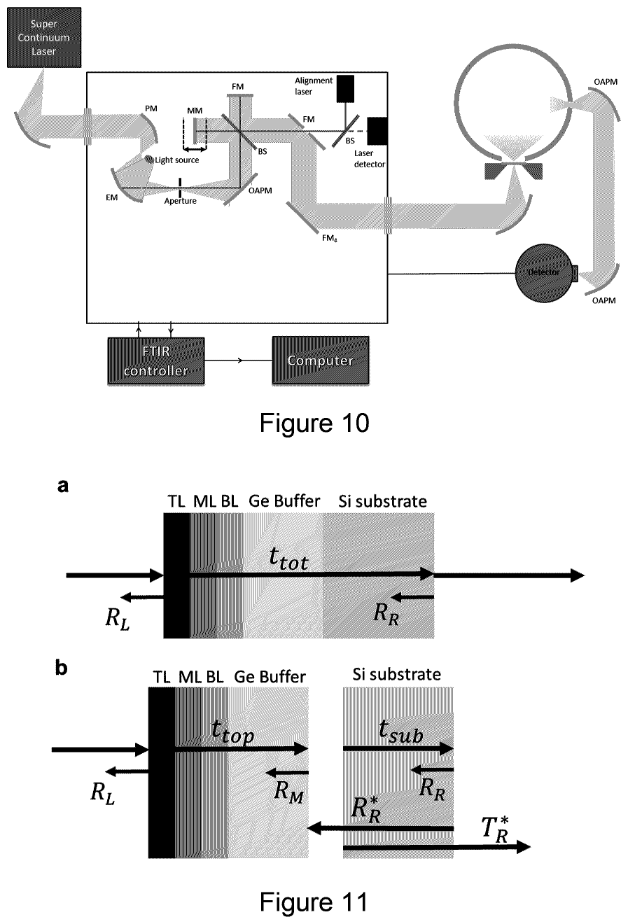

To interpret how the absorption coefficients follows from the measured transmission T, the propagation of a ray of light through a sample is considered as shown in FIGS. 10(a-b). The two processes that are taken into account are absorption when the ray of light travels through a layer and reflection at every refractive-index-changing interface. The transmission (not absorbed light) through a layer i is given by tᵢ=exp(−60 ᵢ⋅dᵢ) where αᵢ is the absorption coefficient of the respective layer and dᵢ the thickness. The reflections Rᵢⱼ at the interfaces are determined using the Fresnel equations for perpendicular incidence give in equation S1 when the light ray travels from medium i to j. Here nᵢ and nⱼ are the refractive indices of the respective media.

$${R}_{i , j} = {\vert \frac{{n}_{i} - {n}_{j}}{{n}_{i} + {n}_{j}} \vert}^{2} \qquad ( eq . S1 )$$

Modelling the ray of light through the full sample can be done in two different approaches. Firstly, we can assume that the only significant reflections occur at the air-sample interfaces (FIG. 10a) and that the refractive indices inside the sample are comparable. Additionally, the refractive index changes gradually throughout the sample from high, on the Sn-rich GeSn side to low on the silicon side. This means that the light expands adiabatically into the material and that reflections are suppressed. The lack of reflections between the layers in the sample means that the transmission through the layers can simply be multiplied resulting in an effective transmission tₜₒₜ given by equation S2.

$${t}_{tot} = {\prod }_{i} {t}_{i} = exp ( {\sum }_{i} - {α}_{i} \cdot {d}_{i} ) = exp ( - A ) \qquad ( eq . S2 )$$

In equation S2 also the absorbance A is introduced, defined as in equation S3. The absorbance is a variable that linearly scales with the absorption coefficient αᵢ but is experimentally more easily accessible yet can be interpreted similarly.

$$A = {\sum }_{i} {A}_{i} = {\sum }_{i} {α}_{i} \cdot {d}_{i} \qquad ( eq . S3 )$$

In FIGS. 10(a-b), there are illustrated schematics of all reflections taken into account for the determination of the total transmission Tₜₒₜ. Where in (a) only the reflections at the outside of the samples are taken into account (equation S4) and in (b) the additional reflection on the germanium-silicon interface (equation S5). In this figure tₓ is a transmission through a respective medium, Rₓ is a reflection between two media and R*ₓ and T*ₓ are the effective reflection and transmission through a layer taking into account multiple reflections.

When taking into account multiple reflections on both sides of the sample the general equation S4 is found^{1.2} in which T*ₜₒₜ is the net transmission measured through the sample.

$${T}_{tot} = \frac{( 1 - {R}_{L} ) \cdot ( 1 - {R}_{R} ) \cdot {t}_{tot}}{1 - {t}_{tot}^{2} \cdot {R}_{L} \cdot {R}_{R}} \qquad ( eq . S4 )$$

A second, more exact approach is to also consider the reflections at the germanium-silicon interface inside the sample as depicted in FIGS. 10(a-b). The reason that only this interface is relevant is because the refractive index of Ge (n_{Ge}=4.2) is barely different from the indices of GeSn alloys where Si (n_{Si}3.4) does make a contrast. Calculating the net transmission Tₜₒₜ through a multilayer sample requires a more thorough approach^{1.3} given in equation S5.

$${T}_{tot} = \frac{( 1 - {R}_{L} ) \cdot {T}_{R}^{*} \cdot {t}_{top}}{1 - {t}_{top}^{2} \cdot {R}_{L} \cdot {R}_{R}^{*}} \qquad ( eq . S5 )$$

Here the total transmission Tₜₒₜ through the sample depends on the net transmission T*_{R} (given in eq. S6) and the net reflection R*_{R} (given in eq. S7) of the Si substrate while taking into account multiple reflections in the substrate. Note that both expression S4 and S5 neglect interference effects, however the backsides of the measured samples are unpolished and therefore no interference is observed in the measurements, justifying this analysis. Equation S4-S7 depend on tₜₒₚ and t_{sub} which are the net transmission through the top layers and through the silicon substrate respectively. However, in this work no absorption in the relevant wavelength regime is expected from the silicon substrate which allows us to choose t_{sub}=1 and tₜₒₚ=tₜₒₜ.

$${R}_{R}^{*} = {R}_{M} + \frac{{( 1 - {R}_{M} )}^{2} \cdot {R}_{R} \cdot {t}_{sub}^{2}}{1 - {R}_{M} \cdot {R}_{R} \cdot {t}_{sub}^{2}} \qquad ( eq . S6 )$$

$${T}_{R}^{*} = \frac{( 1 - {R}_{M} ) \cdot ( 1 - {R}_{R} ) \cdot {t}_{sub}}{1 - {R}_{M} \cdot {R}_{R} \cdot {t}_{sub}^{2}} \qquad ( eq . S7 )$$

Using the above-mentioned simplification both equation S4 and S5 can be solved for tₜₒₜ and can be plotted as a function of the measured transmission Tₜₒₜ, as depicted in FIG. 11(a). For the making of this plot the reflections R_{L}, R_{M} and R_{R} are determined using equation S1 where refractive indices of n_{Si}=3.4 and n_{Ge}=4.2 have been chosen.

In FIG. 11(a), there is illustrated the relation between the measured transmission Tₜₒₜ and the transmission due to non-absorbed light tₜₒₜ. In FIG. 11(b), there is illustrated the relation between Tₜₒₜ and the absorbance (equation S3) of the measured GeSn samples. In the graphs illustrated in FIGS. 11(a-b) no reflections at interfaces are taken into account (black line), only reflections at the air-sample interfaces are taken into account (solid blue line, equation S4) and air-sample interfaces and the Ge—Si interface inside the sample are taken into account (orange dashed line, equation S5). All graphs are calculated using refractive indices of n_{Si}=3.4 and n_{Ge}=4.2.

It becomes apparent from FIG. 11(a) that equation S4 and equation S5 produce almost identical results and that the additional reflection between the germanium and silicon layer can safely be neglected. This result does also show that it is unnecessary to further complicate the model by including reflections between different GeSn layers, which would require the precise estimation of the refractive indices of each layer.

Using equation S2 in combination with equation S4, the absorbance A of the full sample can be found from the measured transmission Tₜₒₜ as also shown in FIG. 11(b). Considering the layers that are relevant in the measured system the absorbance A is given by A=α_{TL}d_{TL}+α_{ML}d_{ML}+α_{BL}d_{BL}+α_{GeVS}d_{GeVS}, as previously mentioned the silicon substrate has no relevant absorption in the probed wavelength regime and is neglected. For energies that are smaller than the band gap of the GeSn middle layer, light is only absorbed in the top layer and A=α_{TL}d_{TL}, thus by dividing this part of the data by d_{TL} the absorption coefficient of the top-layer can be estimated. However, for energies higher that the band gap of the middle layer always more than one layer contribute to the absorption and the interpretation becomes non-trivial.

So far only the absorption due to transitions over the band gap have been considered which are characterised by a wavelength dependent absorption coefficient. However, free-carrier absorption (intra-band absorption) can also have a significant contribution to the total absorption especially in a small band gap material where carriers can be thermally excited and towards the infrared. To compensate for this additional contribution all the found absorption spectra have been baseline corrected such that the absorption coefficient goes to zero for small energies.

Transmittance and absorbance spectra

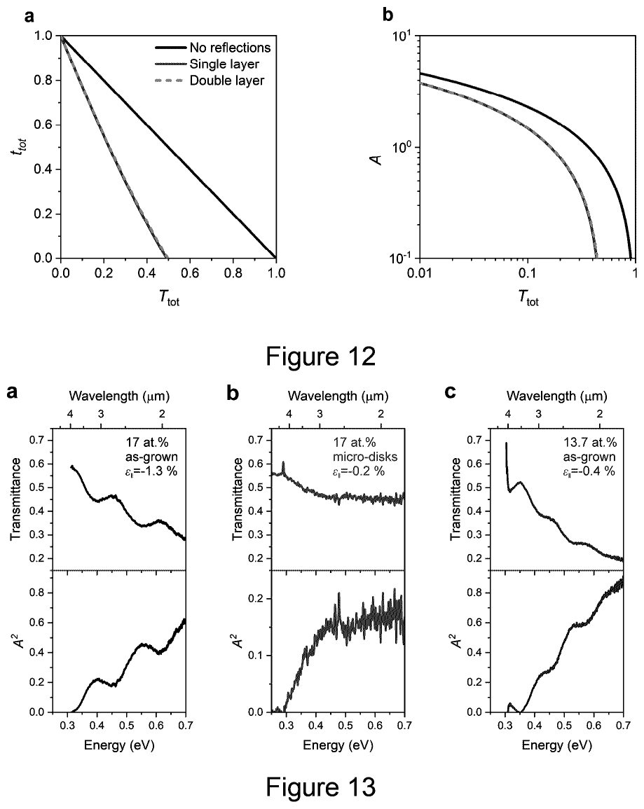

In FIG. 12(a), there is illustrated the transmittance and absorbance of the as-grown Ge_{0.83}Sn_{0.17} sample, measured using a supercontinuum source. In FIG. 12(b), there is illustrated the transmittance and absorbance of the Ge_{0.83}Sn_{0.17} micro-disks, measured using a glow bar. In FIG. 12(c), there is illustrated the transmittance and absorbance of the as-grown Ge_{0.863}Sn_{0.137} sample, measured using a supercontinuum source. The A² curve is a derived function from transmission data according to the procedure described in the Appendix A—Supporting Information.

Extrapolated k⋅p band gap at 300 K

In FIGS. 13(a-b), there is illustrated extrapolated 8-band k⋅p band gap value at 300 K based on the temperature dependence of the PL emission for strained and relaxed Ge_{0.83}Sn_{0.17} (a) and Ge_{0.88}Sn_{0.12} (b).

Power-dependent PL measurements on as-grown Ge_{0.83}Sn_{0.17} at 4K.

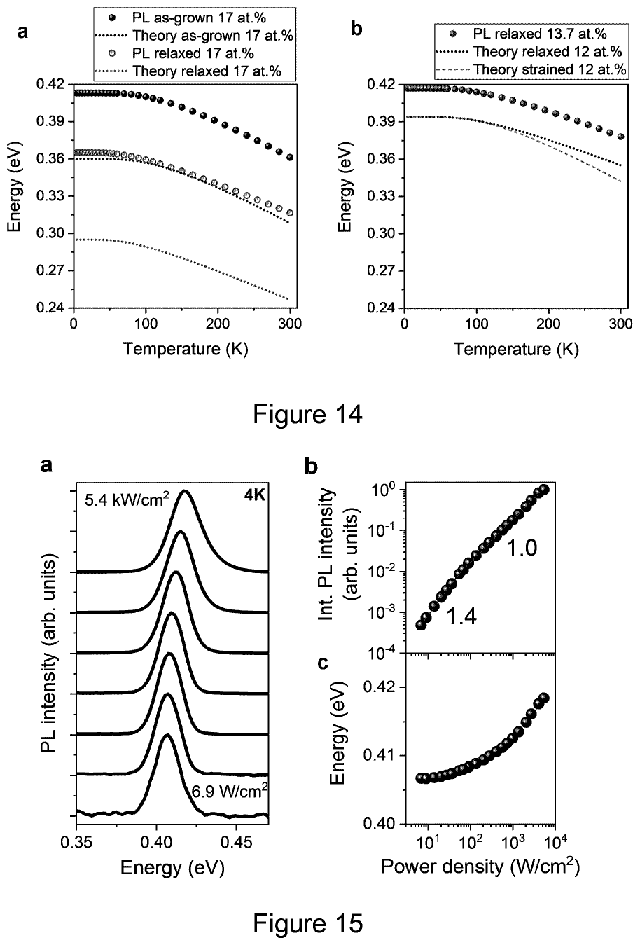

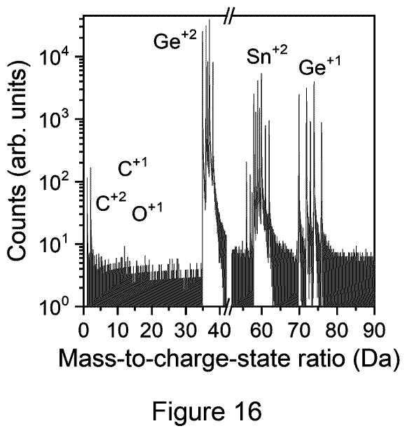

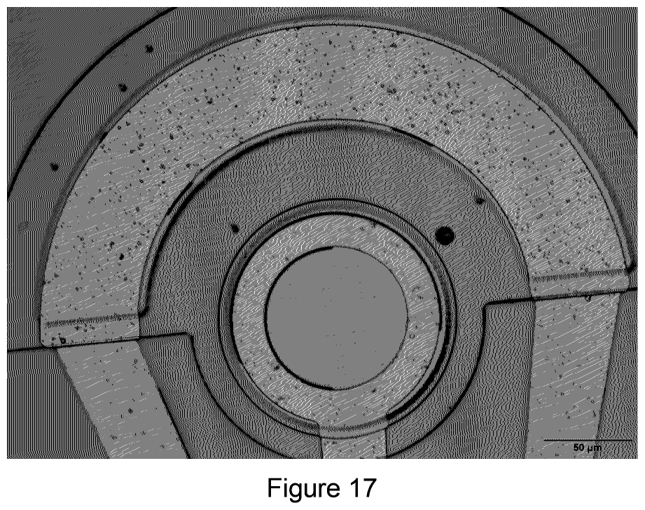

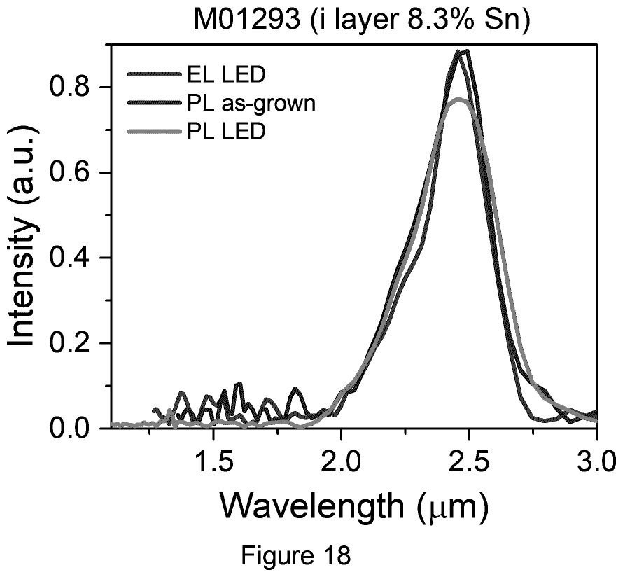

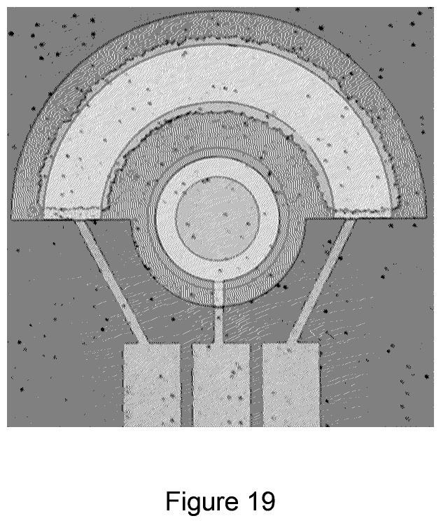

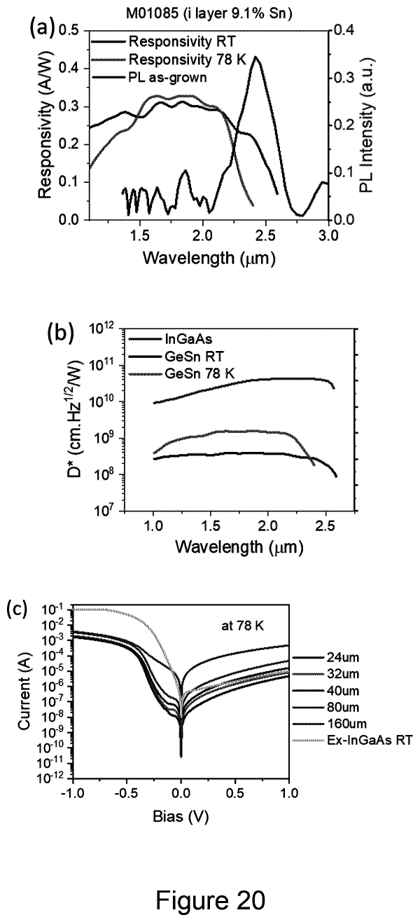

The power-dependent PL spectra acquired in the 6.9 W/cm² to 5.4 kW/cm² range are plotted in FIG. 14(a), while the integrated PL intensity (I_{PL}) and emission energy are plotted as function of the excitation power density (P_{EXC}) are illustrated in FIG. 14(b). Free- and bound-exciton recombination recombination⁴⁻⁶ is observed at low power with a slope m˜1, which is extracted from fitting the data with the power law I_{PL} –P_{EXC}^{m}, and a constant emission energy. At higher excitation power band to band emission is visible, where a Burstein-Moss effect⁷ with blue-shift of 2-6 meV/decade is estimated.

Absence of impurities in atom probe tomography (APT) measurement

FIG. 15 illustrates the mass spectrum extracted from the APT measurements of Ge_{0.83}Sn_{0.17} from Ref.⁸.

### References for the Appendix A—Supporting Information

(1) Ariel, V.; Garber, V.; Bahir, G.; Krishnamurthy, S.; Sher, A. Monitoring HgCdTe Layer Uniformity by the Differential Absorption Technique. Appl. Phys. Lett. 1996, 69 (13), 1864-1866. https://doi.org/10.1063/1.117459.

(2) Finkman, E.; Schacham, S. E. The Exponential Optical Absorption Band Tail of Hg1-XCdxTe. J. Appl. Phys. 1984, 56 (10), 2896-2900. https://doi.org/10.1063/1.333828.

(3) Hougen, C. A. Model for Infrared Absorption and Transmission of Liquid-Phase Epitaxy HgCdTe. J. Appl. Phys. 1989, 66 (8), 3763-3766. https://doi.org/10.1063/1.344038.

(4) Schmidt, T.; Lischka, K.; Zulehner, W. Excitation-Power Dependence of the near-Band-Edge Photoluminescence of Semiconductors. Phys. Rev. B 1992, 45 (16), 8989-8994. https://doi.org/10.1103/PhysRevB.45.8989.

(5) Kaufmann, U.; Kunzer, M.; Maier, M.; Obloh, H.; Ramakrishnan, a.; Santic, B.; Schlotter, P. Nature of the 2.8 EV Photoluminescence Band in Mg Doped GaN. Appl. Phys. Lett. 1998, 72 (11), 1326-1328. https://doi.org/10.1063/1.120983.

(6) Assali, S.; Greil, J.; Zardo, I.; Belabbes, A.; De Moor, M. W. A.; Koelling, S.; Koenraad, P. M.; Bechstedt, F.; Bakkers, E. P. A. M.; Haverkort, J. E. M. Optical Study of the Band Structure of Wurtzite GaP Nanowires. J. Appl. Phys. 2016, 120 (4). https://doi.org/10.1063/1.4959147.

(7) Burstein, E. Anomalous Optical Absorption Limit in InSb. Phys. Rev. 1954, 93, 632-633.

(8) Assali, S.; Nicolas, J.; Mukherjee, S.; Dijkstra, A.; Moutanabbir, 0. Atomically Uniform Sn-Rich GeSn Semiconductors with 3.0-3.5 Mm Room-Temperature Optical Emission. Appl. Phys. Lett. 2018, 112 (25), 251903. https://doi.org/10.1063/1.5038644.

1-181. (canceled)

182. An optoelectronic device, comprising:
a silicon-based substrate;
a heterostructure at least partially extending over the silicon-based substrate, the heterostructure comprising a stack of coextending photoactive layers, each photoactive layer comprising at least two group IV elements and being configured for absorbing short-wave infrared and mid-wave infrared radiation, the short-wave infrared and mid-wave infrared radiation being in a wavelength range extending from about 1 μm to about 8 μm; and
electrodes operatively connected to the heterostructure.

183. The optoelectronic device of claim 182, wherein said at least two group IV elements are selected from the group consisting of: Si, Ge and Sn.

184. The optoelectronic device of claim 182, wherein the wavelength range extends from about 2 μm to about 8 μm, from about 1 μm to about 1.7 μm, from about 1 μm to about 2.7 μm, from about 1 μm to about 3.3 μm, or from about 1 μm to about 3.5 μm.

185. The optoelectronic device of claim 182, wherein the stack of coextending photoactive layers comprises at least one GeSn-based layer.

186. The optoelectronic device of claim 182, wherein the stack of coextending photoactive layers comprises at least two GeSn-based layers, each of said at least two GeSn-based layers having a different chemical composition one from another, the different chemical composition comprising an Sn content, the Sn content being comprised in a range extending between 1 at % and 25 at %, each of said at least two GeSn-based layers having a different lattice strain one from another.

187. The optoelectronic device of claim 182, further comprising a Ge virtual substrate extending over the silicon-based substrate.

188. The optoelectronic device of claim 182, wherein the optoelectronic device is operable at room temperature.

189. The optoelectronic device of claim 182, wherein the optoelectronic device is operable at a cryogenic temperature the cryogenic temperature being equal or greater than about 77 K.

190. A light-emitting diode, comprising:
a silicon-based substrate;
a heterostructure at least partially extending over the silicon-based substrate, the heterostructure comprising a stack of coextending photoactive layers, each photoactive layer comprising at least two group IV elements and being configured for emitting short-wave infrared and mid-wave infrared radiation, the short-wave infrared and mid-wave infrared radiation being in a wavelength range extending from about 1 μm to about 8 μm; and
electrodes operatively connected to the heterostructure.

191. The light-emitting diode of claim 190, wherein said at least two group IV elements are selected from the group consisting of: Si, Ge and Sn.

192. A method for manufacturing an optoelectronic device, comprising:
conditioning a reactor chamber to reach initial growth conditions;
forming a heterostructure on a substrate provided inside the reactor chamber, comprising:
forming a first group IV alloy layer by exposing the substrate to the initial growth conditions;
conditioning the reactor chamber to reach subsequent growth conditions; and
forming at least one subsequent group IV alloy layer on the group IV alloy layer by exposing the first group IV alloy layer to the subsequent growth conditions, each group IV alloy layer in the heterostructure having a different or relatively similar Sn content one from another;
releasing the heterostructure from the substrate to form a relaxed membrane; and
transferring the relaxed membrane on a host substrate.

193. The method of claim 192, wherein the group IV alloy layers comprises at least two group IV elements selected from the group consisting of Si, Ge and Sn.

194. The method of claim 192, further comprising n-doping at least one of the group IV alloy layers and/or p-doping at least one of the group IV alloy layers.

195. The method of claim 192, further comprising forming group IV alloy multi-quantum wells.

196. The method of claim 192, further comprising patterning the heterostructure to obtain an array of structures.

197. The method of claim 192, wherein the substrate comprises a virtual substrate layer extending over an original substrate layer and wherein said releasing the heterostructure from the substrate comprises etching portions of the heterostructure and the virtual substrate until the heterostructure collapses on the original substrate.

198. The method of claim 197, wherein said etching the portions of the heterostructure and the virtual substrate comprises:
anisotropically etching the portions of the heterostructure and portions of the virtual substrate with Cl₂; and
isotropically etching remaining portions of the virtual substrate with CF₄.

199. The method of claim 192, further comprising forming a metallic contact operatively connecting the heterostructure with the substrate.

200. The method of claim 192, wherein said forming the heterostructure comprises forming at least one GeSn-based layers.

201. The method of claim 192, wherein said forming the heterostructure comprises forming at least two GeSn-based layers, each of said at least two GeSn-based layers having a different chemical composition one from another, the different composition comprising an Sn content, the Sn content being comprised in a range extending between 1 at % and 25 at %, each of said at least two GeSn-based layers having a different lattice strain one from another.
